(19) United States
(12) Patent Application Publication
(10) Pub. No.: US 2026/0181789 A1
(43) Pub. Date: Jun. 25, 2026

(54) PRINTED CIRCUIT BOARD ASSEMBLY AND MANUFACTURING METHOD THEREFOR

(71) Applicant: Samsung Electronics Co., Ltd., Suwon-si (KR)

(72) Inventors: Juho KIM, Suwon-si (KR); Woochul PARK, Suwon-si (KR); Kiwoong KIM, Suwon-si (KR); Yousok MIN, Suwon-si (KR)

(21) Appl. No.: 19/536,853

(22) Filed: Feb. 11, 2026

Related U.S. Application Data
(63) Continuation of application No. PCT/KR2024/009853, filed on Jul. 10, 2024.

(30) Foreign Application Priority Data
Aug. 13, 2023 (KR) 10-2023-0105986
Oct. 4, 2023 (KR) 10-2023-0131994

(51) Int. Cl. H05K 3/3485; H05K 1/181; H05K 3/341

(52) U.S. Cl. CPC H05K 3/3485; H05K 1/181; H05K 3/3436; H05K 2201/10121

(57) ABSTRACT

A printed circuit board assembly (PBA) is provided. The printed circuit board assembly includes an electronic component, a printed circuit board (PCB) on which the electronic component is disposed, a plurality of solder members electrically connecting the electronic component and the printed circuit board between the printed circuit board and the electronic component, a plurality of protrusions disposed to be spaced apart from the plurality of solder members on the printed circuit board and positioned near an edge of the electronic component, and a filling member filling the edge of the electronic component between the printed circuit board and the electronic component, wherein. distribution of the filling member is facilitated by an adhesive force between the filling member and the plurality of protrusions, and a cohesive force of the filling member during the filling of the filling member in a liquid state between the printed circuit board and the electronic component.

### CROSS-REFERENCE TO RELATED APPLICATION(S)

This application is a continuation application, claiming priority under 35 U.S.C. § 365(c), of an International application No. PCT/KR2024/009853, filed on Jul. 10, 2024, which is based on and claims the benefit of a Korean patent application number 10-2023-0105986, filed on Aug. 13, 2023, in the Korean Intellectual Property Office, and of a Korean patent application number 10-2023-0131994, filed on Oct. 4, 2023, in the Korean Intellectual Property Office, the disclosure of each of which is incorporated by reference herein in its entirety.

### BACKGROUND

### 1. Field

The disclosure relates to a printed circuit board assembly (PBA) including an electronic component and a circuit board on which the electronic component is mounted, and a method for manufacturing the same.

### 2. Description of Related Art

Electronic devices are becoming increasingly downsized and multifunctional according to the rapid development of the electronics industry and user demands. Accordingly, the need for miniaturization and multifunctionalization of electronic components (e.g., semiconductor device components) used in electronic devices is also increasing.

An electronic component may be mounted (or disposed) on a circuit board (e.g., printed circuit board (PCB)) using surface mount technology (SMT). The electronic component may be physically connected and electrically connected to the circuit board through a plurality of solder members.

Generally, a plurality of solder members may be disposed in an inner area between the circuit board and the electronic component. The plurality of solder members may not be disposed in an edge area between the circuit board and the electronic component according to a design structure. In this case, the electronic component may have somewhat lower reliability compared to an electronic component having a different design structure.

The above information is presented as background information only to assist with an understanding of the disclosure. No determination has been made, and no assertion is made, as to whether any of the above might be applicable as prior art with regard to the disclosure.

### SUMMARY

Aspects of the disclosure are to address at least the above-mentioned problems and/or disadvantages and to provide at least the advantages described below. Accordingly, an aspect of the disclosure is to provide a printed circuit board assembly (PBA) including a plurality of protrusions formed in an edge area of a circuit board where a plurality of solder members are not disposed and a filling member filled in the edge area of the circuit board along the plurality of protrusions.

Additional aspects will be set forth in part in the description which follows and, in part, will be apparent from the description, or may be learned by practice of the presented embodiments.

In accordance with an aspect of the disclosure, a printed circuit board assembly is provided. The printed circuit board assembly includes an electronic component, a printed circuit board (PCB) on which the electronic component is mounted, a plurality of solder members electrically connecting the electronic component and the printed circuit board between the printed circuit board and the electronic component, a plurality of protrusions disposed to be spaced apart from the plurality of solder members on the printed circuit board and positioned near an edge of the electronic component, and a filling member filling the edge of the electronic component between the printed circuit board and the electronic component, wherein distribution of the filling member is facilitated by an adhesion force between the filling member and the plurality of protrusions, and a cohesion force of the filling member during filling of the filling member in a liquid state between the printed circuit board and the electronic component.

In accordance with another aspect of the disclosure, a method for manufacturing a printed circuit board assembly including a printed circuit board on which an electronic component is disposed is provided. The method includes forming a plurality of protrusions in an edge area of the printed circuit board spaced apart from a soldering area of the printed circuit board where a plurality of solder members are disposed, applying a soldering material to a plurality of connection pads disposed in the soldering area, mounting the electronic component on the printed circuit board such that the plurality of protrusions and an edge of the electronic component face each other, and filling a filling member between the plurality of protrusions disposed between the mounted electronic component and the printed circuit board, wherein distribution of the filling member is facilitated by an adhesion force between the filling member and the plurality of protrusions, and a cohesion force of the filling member during the filling of the filling member in a liquid state between the printed circuit board and the electronic component.

According to various embodiments of the disclosure, as a plurality of protrusions are formed in an edge area of a circuit board where a plurality of solder members are not disposed, a filling member is evenly filled (or applied) in the edge area along the plurality of protrusions. In this case, an electronic component is firmly mounted on a substrate by a plurality of solder members and a filling member, thereby enhancing reliability of a printed circuit board assembly.

Other aspects, advantages, and salient features of the disclosure will become apparent to those skilled in the art from the following detailed description, which, taken in conjunction with the annexed drawings, discloses various embodiments of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a plan view illustrating a printed circuit board assembly (PBA) according to an embodiment of the disclosure;

FIG. 2A is a cross-sectional view illustrating the printed circuit board assembly taken along line I-I′ illustrated in FIG. 1 according to an embodiment of the disclosure;

FIG. 2B is a partial cross-sectional view illustrating the printed circuit board assembly illustrating a state before a filling member is filled, according to an embodiment of the disclosure;

FIGS. 3A and 3B are partial cross-sectional views illustrating the printed circuit board assembly illustrating a state in which a filling member is filled, according to an embodiment of the disclosure;

FIG. 4 is an enlarged view of portion A of FIG. 1 according to an embodiment of the disclosure;

FIGS. 5A and 5B are cross-sectional views illustrating cross-sectional shapes of a plurality of protrusions according to an embodiment of the disclosure;

FIGS. 6A and 6B are views illustrating an arrangement of a plurality of protrusions according to an embodiment of the disclosure;

FIGS. 7A and 7B are views illustrating an arrangement of a plurality of protrusions according to an embodiment of the disclosure;

FIGS. 8A and 8B are views illustrating an arrangement of a plurality of protrusions according to an embodiment of the disclosure;

FIGS. 9A and 9B are views illustrating an arrangement of a plurality of protrusions according to an embodiment of the disclosure;

FIGS. 10A and 10B are views illustrating an arrangement of a plurality of protrusions according to an embodiment of the disclosure;

FIGS. 11A and 11B are views illustrating an arrangement of a plurality of protrusions according to an embodiment of the disclosure;

FIGS. 12A and 12B are views illustrating an arrangement of a plurality of protrusions according to an embodiment of the disclosure;

FIGS. 13A and 13B are views illustrating an arrangement of a plurality of protrusions according to an embodiment of the disclosure;

FIGS. 14A and 14B are views illustrating an arrangement of a plurality of protrusions according to an embodiment of the disclosure;

FIGS. 15A and 15B are views illustrating an arrangement of a plurality of protrusions according to an embodiment of the disclosure;

FIGS. 16A and 16B are views illustrating an arrangement of a plurality of protrusions according to an embodiment of the disclosure;

FIG. 17 is a view illustrating a filling range of a filling member on a circuit board according to an embodiment of the disclosure;

FIG. 18 is a manufacturing process diagram illustrating a printed circuit board assembly according to an embodiment of the disclosure;

FIGS. 19A and 19B are process diagrams illustrating a forming process of a plurality of protrusions according to an embodiment of the disclosure;

FIGS. 20A and 20B are process diagrams illustrating a forming process of a plurality of protrusions according to an embodiment of the disclosure;

FIG. 21 is a plan view illustrating a printed circuit board assembly according to an embodiment of the disclosure;

FIG. 22 is a cross-sectional view illustrating the printed circuit board assembly taken along line II-II′ illustrated in FIG. 21 according to an embodiment of the disclosure;

FIG. 23 is a view illustrating a filling range of a filling member in a circuit board of the disclosure according to an embodiment of the disclosure;

FIG. 24 is a view illustrating a crack state of a solder member occurring in case that a filling member is under-filled according to an embodiment of the disclosure;

FIG. 25 is a view illustrating a filling range of a filling member on a circuit board according to an embodiment of the disclosure; and

FIG. 26 is a view illustrating a crack state of a solder member occurring in case that a filling member is over-filled according to an embodiment of the disclosure.

Throughout the drawings, like reference numerals will be understood to refer to like parts, components, and structures.

### DETAILED DESCRIPTION

The following description with reference to the accompanying drawings is provided to assist in a comprehensive understanding of various embodiments of the disclosure as defined by the claims and their equivalents. It includes various specific details to assist in that understanding but these are to be regarded as merely exemplary. Accordingly, those of ordinary skill in the art will recognize that various changes and modifications of the various embodiments described herein can be made without departing from the scope and spirit of the disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the disclosure. Accordingly, it should be apparent to those skilled in the art that the following description of various embodiments of the disclosure is provided for illustration purpose only and not for the purpose of limiting the disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

As used herein, each of such phrases as “A or B,” “at least one of A and B,” “at least one of A or B,” “A, B, or C,” “at least one of A, B, and C,” and “at least one of A, B, or C,” may include all possible combinations of the items enumerated together in a corresponding one of the phrases.

As used herein, such terms as “1st” and “2nd,” or “first” and “second” may be used to simply distinguish a corresponding component from another, and does not limit the components in other aspect (e.g., importance or order).

It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wiredly), wirelessly, or via a third element.

It will be further understood that the terms “comprise” and/or “have,” as used herein, specify the presence of stated features, integers, steps, operations, elements, and/or components, but do not preclude the presence or addition of one or more other features, integers, steps, operations, elements, components, and/or groups thereof.

It will be understood that when a component is referred to as “connected to,” “coupled to”, “supported on,” or “contacting” another component, the components may be connected to, coupled to, supported on, or contact each other directly or via a third component.

Throughout the specification, when one component is positioned “on” another component, the first component may be positioned directly on the second component, or other component(s) may be positioned between the first and second component.

The term “and/or” may denote a combination(s) of a plurality of related components as listed or any of the components.

Hereinafter, the working principle and embodiments of the disclosure are described with reference to the accompanying drawings.

It should be appreciated that the blocks in each flowchart and combinations of the flowcharts may be performed by one or more computer programs which include instructions. The entirety of the one or more computer programs may be stored in a single memory device or the one or more computer programs may be divided with different portions stored in different multiple memory devices.

Any of the functions or operations described herein can be processed by one processor or a combination of processors. The one processor or the combination of processors is circuitry performing processing and includes circuitry like an application processor (AP, e.g. a central processing unit (CPU)), a communication processor (CP, e.g., a modem), a graphics processing unit (GPU), a neural processing unit (NPU) (e.g., an artificial intelligence (AI) chip), a wireless fidelity (Wi-Fi) chip, a Bluetooth® chip, a global positioning system (GPS) chip, a near field communication (NFC) chip, connectivity chips, a sensor controller, a touch controller, a finger-print sensor controller, a display driver integrated circuit (IC), an audio CODEC chip, a universal serial bus (USB) controller, a camera controller, an image processing IC, a microprocessor unit (MPU), a system on chip (SoC), an IC, or the like.

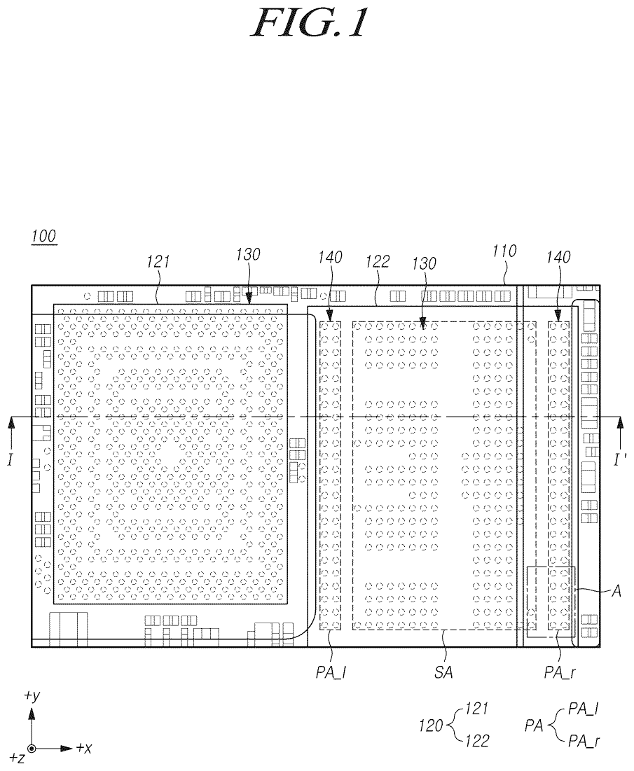

FIG. 1 is a plan view illustrating a printed circuit board assembly (PBA) according to an embodiment of the disclosure.

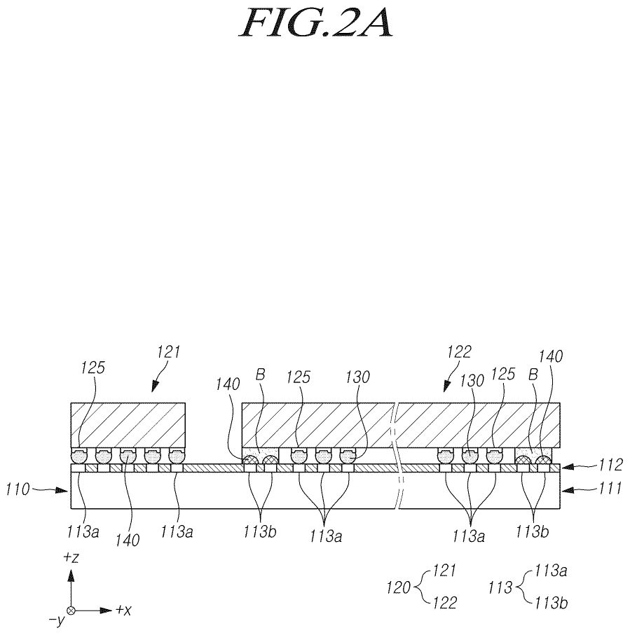

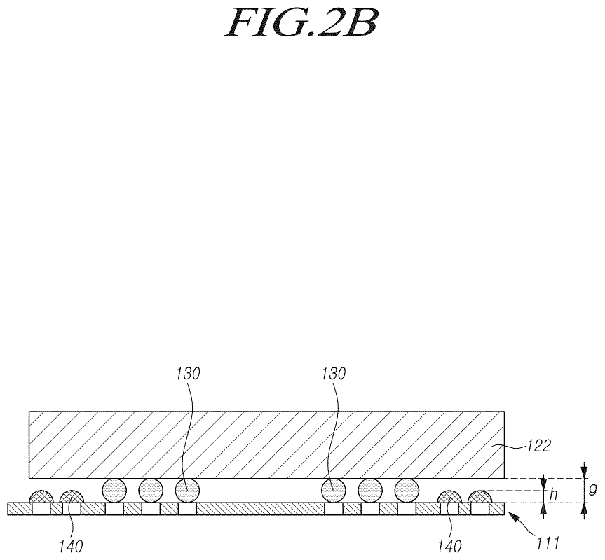

FIG. 2A is a cross-sectional view illustrating the printed circuit board assembly taken along line I-I′ illustrated in FIG. 1 according to an embodiment of the disclosure.

FIG. 2B is a partial cross-sectional view illustrating the printed circuit board assembly illustrating a state before a filling member is filled, according to an embodiment of the disclosure.

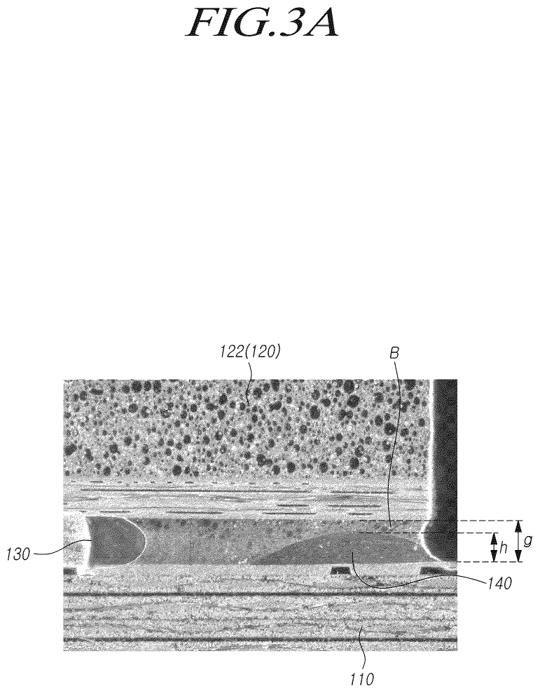

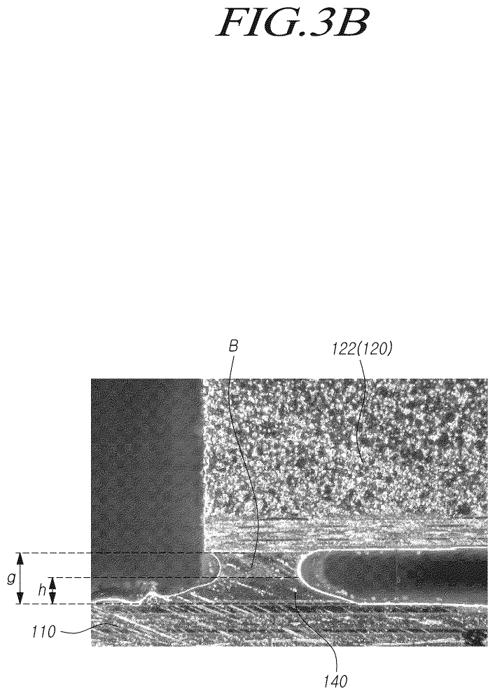

FIGS. 3A and 3B are partial cross-sectional views illustrating the printed circuit board assembly illustrating a state in which a filling member is filled, according to an embodiment of the disclosure.

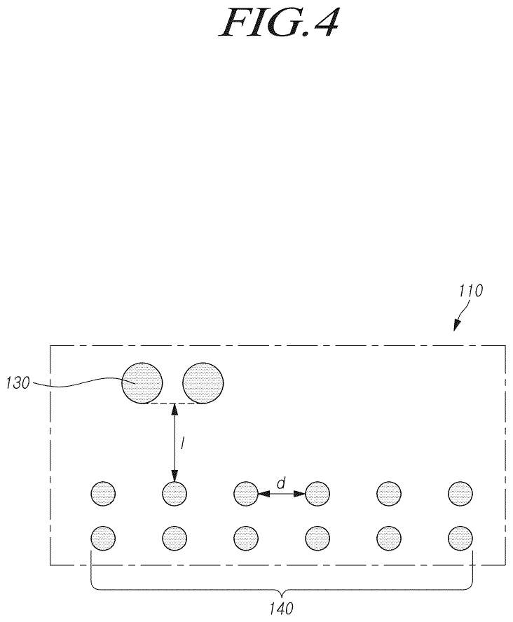

FIG. 4 is an enlarged view of portion A of FIG. 1 according to an embodiment of the disclosure.

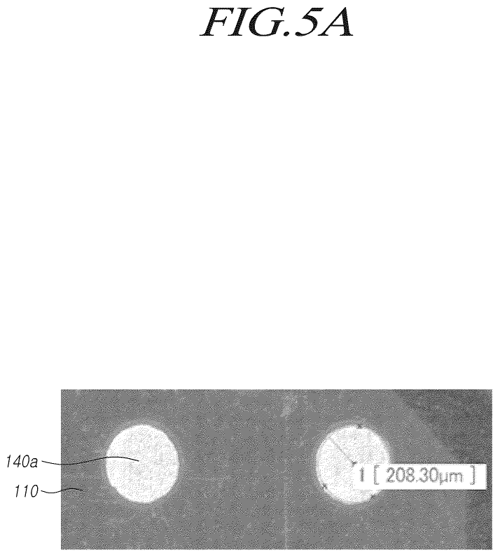

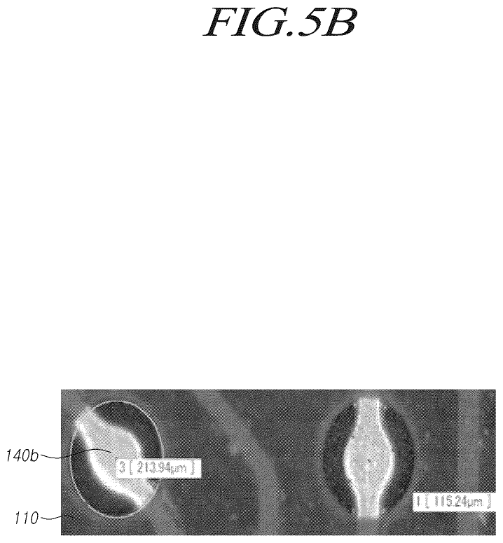

FIGS. 5A and 5B are cross-sectional views illustrating cross-sectional shapes of a plurality of protrusions according to an embodiment of the disclosure.

A printed circuit board assembly 100 according to an example of the disclosure may be implemented as various types of modules such as a solid state drive (SSD) module, a memory module, a computer system module, or a mobile system module. For example, the printed circuit board assembly 100 may correspond to a semiconductor module.

Hereinafter, in describing the disclosure, the printed circuit board assembly 100 implemented as a semiconductor module is described as an example, but the disclosure is not limited thereto.

Referring to FIGS. 1, 2A, 2B, 3A, 3B, 4, 5A and 5B, a printed circuit board assembly 100 according to an example may include a circuit board (e.g., printed circuit board (PCB)) 110, at least one electronic component 120, a plurality of solder members 130, a plurality of protrusions 140, and/or a filling member B.

According to an example, various components (e.g., electronic components) constituting the printed circuit board assembly 100 may be mounted or disposed on the circuit board 110.

According to an example, the circuit board 110 may be provided with one or more circuit traces on at least one surface to electrically connect various components mounted on the circuit board 110. In an example, the circuit board 110 may be configured as a substrate for a single layer printed circuit board having one or more circuit traces formed on only one surface. In an example, the circuit board 110 may be configured as a substrate for a double layer printed circuit board having one or more circuit traces formed on two opposite surfaces. For example, in case that the circuit board 110 is configured for a double layer printed circuit board, upper and lower one or more circuit traces may be electrically connected through a conductive via structure (e.g., conductive via hole) penetrating the circuit board 110 (e.g., a substrate body 111 described below).

According to an example, the circuit board 110 may include a substrate body 111, a protective layer 112, and/or a plurality of substrate pads 113.

According to an example, the substrate body 111 may include a body layer formed by compressing various resins such as glass epoxy (or FR-4) resin, phenol resin, or BT resin to a predetermined thickness, and one or more circuit traces formed on the body layer. The one or more circuit traces may be formed by, e.g., patterning a copper foil coated on the body layer.

In an example, the substrate body 111 may have a structure in which the number of copper foil layers is formed to be three or more using an insulator called prepreg, and one or more circuit traces is formed in three or more layers according to the number of copper foil layers, but the disclosure is not limited thereto.

According to an example, the protective layer 112 may be disposed on an upper side (e.g., +z-axis direction) of the substrate body 111. In an example, the protective layer 112 may be configured to protect the one or more circuit traces formed on the substrate body 111. The protective layer 112 may be formed of, e.g., a solder resist (SR) covering the one or more circuit traces. The protective layer 112 may have a structure that covers the one or more circuit traces while opening portions of the plurality of substrate pads 113 to the outside.

According to an example, the plurality of substrate pads 113 may be disposed on at least an upper surface (e.g., a surface facing the +z-axis direction) or a lower surface (e.g., a surface facing the −z-axis direction) of the circuit board 110. Although not specifically illustrated in the drawings, the plurality of substrate pads 113 may also be electrically connected to other substrates in addition to the electronic component 120. In an example, the plurality of substrate pads 113 may be provided on the substrate body 111. In an example, the plurality of substrate pads 113 may be disposed on substantially the same plane (e.g., X-Y plane) as the protective layer 112, but the disclosure is not limited thereto.

According to an example, the plurality of substrate pads 113 may have various shapes. For example, the plurality of substrate pads 113 may have shapes such as circular, polygonal, or ring shapes, but the disclosure is not limited thereto.

According to an example, the plurality of substrate pads 113 may include a plurality of connection pads 113a and/or a plurality of dummy pads 113b.

According to an example, the plurality of connection pads 113a may be electrically connected to at least one electronic component 120. In an example, each of the plurality of connection pads 113a may electrically connect the electronic component 120 and the circuit board 110 through the plurality of solder members 130.

According to an example, the plurality of connection pads 113a may be provided integrally with the one or more circuit traces as a portion of the one or more circuit traces, or may be provided as separate components on the one or more circuit traces. The plurality of connection pads 113a may be referred to as, e.g., electrode pads, contact pads, solder pads, or soldering pads. The plurality of connection pads 113a may be formed of at least one of, e.g., aluminum (Al), copper (Cu), nickel (Ni), tungsten (W), platinum (Pt), or gold (Au).

According to an example, the plurality of connection pads 113a may be disposed on a lower side (e.g., −z-axis direction) of the electronic component 120. In an example, the plurality of connection pads 113a may be disposed on the circuit board 110 to overlap the electronic component 120. In an example, the plurality of connection pads 113a may be disposed in a soldering area SA where the plurality of solder members 130 are disposed. In this case, as illustrated in FIG. 1, in case of viewing the printed circuit board assembly 100 from top to bottom, the plurality of connection pads 113a are hidden by the electronic component 120.

According to an example, the plurality of dummy pads 113b are not related to electrical connection to the electronic component 120 and may be formed on the circuit board 110 as an intermediary for fixing the protrusions 140.

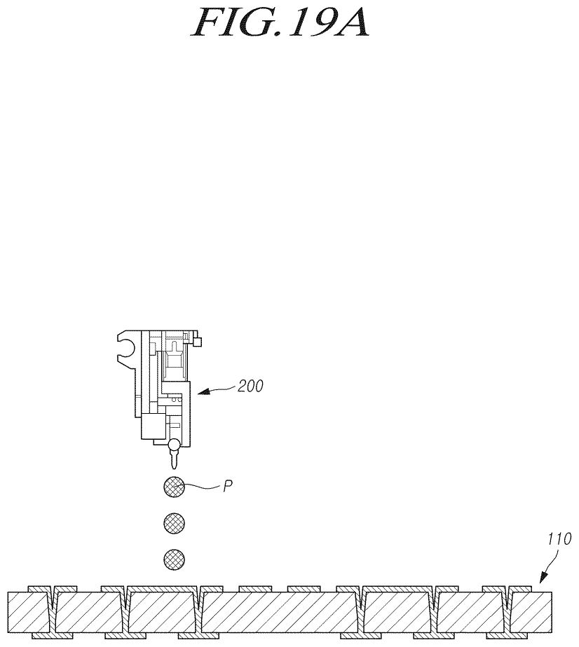

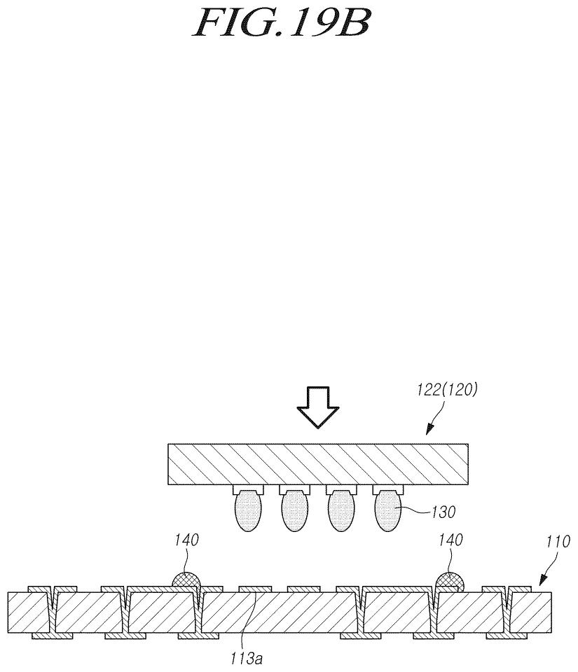

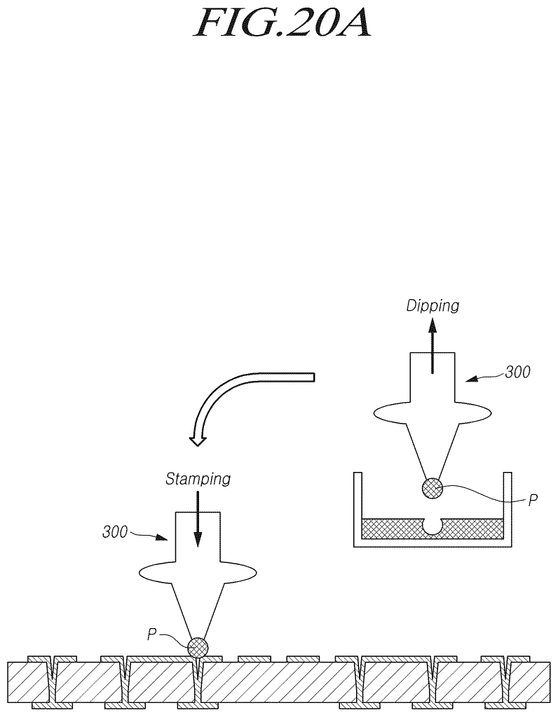

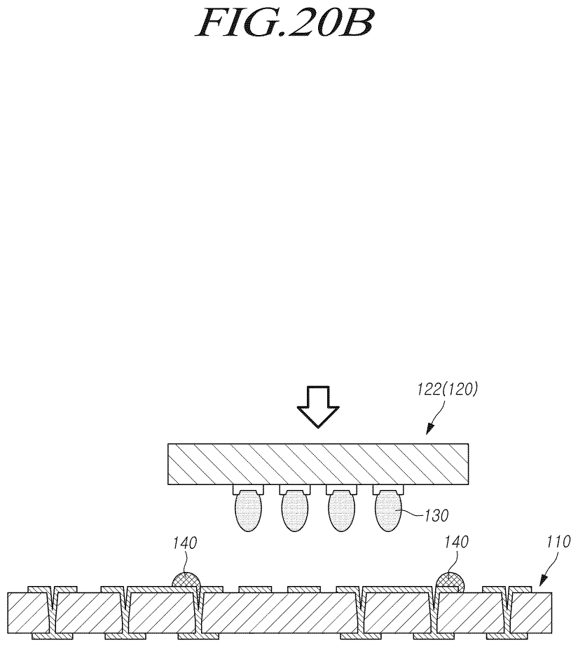

According to an example, the plurality of dummy pads 113b may be formed in one process together with the plurality of connection pads 113a. However, the disclosure is not limited thereto, and the plurality of dummy pads 113b may be omitted considering a forming process of the plurality of protrusions 140 and design conditions of the circuit board 110. For example, in case of forming the plurality of protrusions 140 using a bonding member P described below, the plurality of dummy pads 113b may be omitted. Hereinafter, the forming process of the plurality of protrusions 140 using the bonding member P is described in detail with reference to FIGS. 19 and 20.

According to an example, the plurality of dummy pads 113b may be disposed on a lower side (e.g., −z-axis direction) of the electronic component 120. In an example, the plurality of dummy pads 113b may be disposed on the circuit board 110 to overlap the electronic component 120 (e.g., the second electronic component 122). In an example, the plurality of dummy pads 113b may be disposed in a periphery (or vicinity) of the soldering area SA. For example, the plurality of dummy pads 113b may be spaced apart from the plurality of connection pads 113a. In an example, the plurality of dummy pads 113b may be disposed in an edge area PA where the plurality of solder members 130 are not disposed. The edge area PA may mean an area formed between the second electronic component 122 and the circuit board 110, adjacent to or facing an edge or boundary of the second electronic component 122 in case that the second electronic component 122 is mounted (or disposed) on the circuit board 110.

According to an example, the edge area PA may include a first edge area PA_l formed on a left side (e.g., −x-axis direction) with respect to the soldering area SA and a second edge area PA_r formed on a right side (e.g., +x-axis direction) with respect to the soldering area SA.

In an example, the first edge area PA_l may be formed to extend along a vertical direction (e.g., ±y-axis direction) on the circuit board 110. In an example, the second edge area PA_r may be formed to extend along the vertical direction (e.g., ty-axis direction) on the circuit board 110.

Although not specifically illustrated in the drawings, the edge area PA may be formed in various shapes to overlap the second electronic component 122 according to an electrical connection structure of the second electronic component 122, e.g., an arrangement form of the plurality of solder members 130 and/or an arrangement form of a plurality of contact points 125 described below. For example, unlike that illustrated in FIG. 1, the edge area PA may be formed on all four sides of the soldering area SA to surround the soldering area SA. In this case, as illustrated in FIG. 1, in case of viewing the printed circuit board assembly 100 from top to bottom, the plurality of dummy pads 113b are hidden by the electronic component 120.

According to an example, at least one electronic component 120 may be mounted (or disposed) on the circuit board 110. For example, at least one electronic component 120 may be mounted on at least one surface (e.g., upper surface or lower surface) of the circuit board 110. In an example, at least one electronic component 120 may be electrically/physically connected to the circuit board 110 through the plurality of solder members 130.

According to an example, at least one electronic component 120 may include various elements such as passive elements and/or active elements. At least one electronic component 120 may be any element that may be mounted (or disposed) on the circuit board 110.

In an example, at least one electronic component 120 may include a plurality of contact points 125 formed on one surface (e.g., lower surface) facing the circuit board 110 in case that the electronic component 120 is mounted (or disposed) on the circuit board 110. In an example, the plurality of contact points 125 may contact the plurality of solder members 130. The plurality of contact points 125 may be electrically connected to the plurality of connection pads 113a provided on the circuit board 110 through the plurality of solder members 130.

According to an example, at least one electronic component 120 may be a chip package including at least one semiconductor chip. For example, the electronic component 120 may include at least one memory chip or logic chip therein. For example, in case that the electronic component 120 includes a memory chip, the electronic component 120 may be a memory element including memory such as dynamic random access memory (DRAM), static random access memory (SRAM), flash memory, electrically erasable programmable read-only memory (EEPROM), phase-change random access memory (PRAM), magnetoresistive random access memory (MRAM), or resistive random access memory (RRAM). For example, in case that the electronic component 120 includes a logic chip, the electronic component 120 may be a logic element including a relatively small-sized logic chip.

In an example, at least one electronic component 120 may include elements such as a connector, a controller, or an electrolytic cap. Here, the electrolytic cap may be a unipolar capacitor, may have a large capacitance, and may be used for a low frequency filter or a bypass.

In an example, at least one electronic component 120 may include a chip package such as a generally large-sized micro-processor, central processing unit (CPU), controller, or application specific integrated circuit (ASIC).

In an example, at least one electronic component 120 may also include a system on chip (SoC) type application processor (AP) used in mobile electronic devices.

The types of at least one electronic component 120 are not limited to the above-described elements.

In an example, at least one electronic component 120 may be mounted (or disposed) on the circuit board 110 through surface mount technology (SMT). The SMT may mean a so-called automatic soldering technology that automatically mounts an electronic component on a surface of the circuit board 110 using a soldering material (or solder paste). For example, the SMT may denote a technology of automatically mounting (or disposing) electronic components such as semiconductors, diodes, and chips on a substrate using equipment such as a chip mounter or multi mounter using a soldering material and curing them. In such SMT, heat and pressure may be applied to facilitate bonding of the corresponding electronic component with the soldering material.

According to an example, at least one electronic component 120 may include a first electronic component 121 and a second electronic component 122.

According to an example, the first electronic component 121 may correspond to an electronic component having substantially the same size as a soldering area SA where the plurality of solder members 130 are disposed. The first electronic component 121 may correspond to, e.g., an AP-related component.

According to an example, the second electronic component 122 may correspond to a component having a different size from the first electronic component 121. For example, the second electronic component 122 may have a larger size than the first electronic component 121.

According to an example, the second electronic component 122 may correspond to an electronic component having a different size from the soldering area SA where the plurality of solder members 130 are disposed. The second electronic component 122 may correspond to, e.g., an electronic component including the soldering area SA and the edge area PA. The second electronic component 122 may correspond to, e.g., a memory-related component.

According to an example, the plurality of solder members 130 may be disposed on the circuit board 110 to overlap the electronic component 120. In an example, the plurality of solder members 130 may be disposed on the plurality of connection pads 113a. In an example, the plurality of solder members 130 may be disposed in the soldering area SA. In an example, the plurality of solder members 130 may physically/electrically connect at least one electronic component 120 and the circuit board 110. For example, the second electronic component 122 may be firmly mounted (or disposed) on the circuit board 110 by the plurality of solder members 130 and the filling member B described below. In an example, the plurality of solder members 130 may include solder balls.

According to an example, the plurality of protrusions 140 may be disposed on the circuit board 110 to overlap the second electronic component 122. In an example, the plurality of protrusions 140 may be disposed on the plurality of dummy pads 113b. For example, the plurality of protrusions 140 may be formed by a soldering process to be disposed on the plurality of dummy pads 113b. The plurality of protrusions 140 may be formed of a soldering material, but the disclosure is not limited thereto. For example, the plurality of protrusions 140 may also be formed by the bonding member P described below, and this is described below with reference to FIGS. 19 and 20.

In an example, the plurality of protrusions 140 may be disposed in the edge area PA. In an example, the plurality of protrusions 140 may be disposed in the edge area PA in at least one or more rows.

According to an example, the plurality of protrusions 140 may have various shapes such as hemispherical shape, cylindrical shape, or polyhedral shape, but the disclosure is not limited thereto. For example, the shape of the plurality of protrusions 140 may be designed considering a filling amount and/or a filling area (or filling range) of the filling member B in case of filling the filling member B. This is because resistance to flow of the filling member B varies according to the shape of the plurality of protrusions 140 in case of filling the filling member B. For example, the plurality of protrusions 140a may be designed to have a circular cross-section cut along the X-Y plane, as illustrated in FIG. 5A. For example, the plurality of protrusions 140b may be designed to have a bar shape with a convex center in a cross-section cut along the X-Y plane, as illustrated in FIG. 5B.

According to an example, the plurality of protrusions 140 may be disposed to be spaced apart from each other at a predetermined interval. For example, a spacing d between the plurality of protrusions 140 may be 0.4 mm or more, but the disclosure is not limited thereto. The spacing d between the plurality of protrusions 140 may be designed considering the filling amount and/or filling area (or filling range) of the filling member B in case of filling the filling member B. The filling area of the filling member B may also be referred to as an overlapping area or bonding area as an area where the filling member B contacts the second electronic component 122 and the circuit board 110. For example, in case that the spacing d between the plurality of protrusions 140 is decreased, capillary action becomes more active, and the filling amount and/or filling area of the filling member B may increase. Here, the capillary action may mean a phenomenon in which the filling member B flows from the edge area PA to the soldering area SA along between the plurality of protrusions 140 due to cohesion of the filling member B and adhesion between the filling member B and the plurality of protrusions 140. In this case, the second electronic component 122 may be firmly mounted (or disposed or fixed) on the circuit board 110.

According to an example, the plurality of protrusions 140 may be disposed to be spaced apart from the plurality of solder members 130 at a predetermined interval. For example, a spacing distance 1 between the plurality of protrusions 140 and the plurality of solder members 130 may be designed within a range of 0.9 mm to 2.0 mm, but the disclosure is not limited thereto. The spacing distance 1 between the plurality of protrusions 140 and the plurality of solder members 130 may be designed considering the filling amount and/or filling area (or filling range) of the filling member B in case of filling the filling member B. For example, the spacing distance 1 may be designed within a range where the filled filling member B does not contact the plurality of solder members 130 in case of filling the filling member B.

According to an example, the plurality of protrusions 140 may protrude to a predetermined height h from a surface of the circuit board 110. In an example, a protruding height h of the plurality of protrusions 140 may be designed to be lower than a gap g between the circuit board 110 and the second electronic component 122 (see FIGS. 2B, FIG. 3A and FIG. 3B). For example, the plurality of protrusions 140 may be designed not to contact a lower surface of the second electronic component 122. For example, the protruding height h of the plurality of protrusions 140 may be designed within a range of 70 μm to 100 μm, but the disclosure is not limited thereto. For example, the gap g between the second electronic component 122 and the circuit board 110 may be designed within a range of 140 μm to 160 μm. For example, a gap between the plurality of protrusions 140 and the second electronic component 122 may be designed within a range of 80 μm to 90 μm. In this case, interference between the plurality of protrusions 140 and the second electronic component 122 does not occur, so damage to the second electronic component 122 due to formation of the plurality of protrusions 140 may be prevented. However, the disclosure is not limited thereto, and in some examples, the protruding height h of the plurality of protrusions 140 may be designed to be substantially the same as the gap g between the circuit board 110 and the second electronic component 122 so that the plurality of protrusions 140 connect the circuit board 110 and the second electronic component 122.

According to an example, a size of the plurality of protrusions 140 may be formed to be smaller than the plurality of solder members 130. For example, a diameter of the plurality of protrusions 140 may be designed within a range of 0.1 mm to 0.2 mm, and a diameter of the plurality of solder members 130 may be designed to be about 0.3 mm, but the disclosure is not limited thereto. In this case, more of the plurality of protrusions 140 may be disposed than the plurality of solder members 130 within a limited area (e.g., the edge area PA), so capillary action may be smoother.

In an example, the plurality of protrusions 140 may adjust the filling amount and/or filling area (or filling range) of the filling member B filled in a space between the second electronic component 122 and the circuit board 110 by designing spacing between protrusions, arrangement of protrusions, and/or shape of protrusions in various ways, and may also enhance uniformity of the filling member B. Here, the uniformity of the filling member B may mean a degree to which the filling member B is evenly applied on the circuit board 110.

According to an example, the filling member B may physically connect the second electronic component 122 to the circuit board 110. In an example, the filling member B may be filled in liquid form in a gap between the circuit board 110 and the second electronic component 122 by an underfill process and/or a sidefill process. Thereafter, the filled filling member B may be cured by heat and/or pressure. In an example, the filling member B may be composed of a non-conductive material. For example, the filling member B may be composed of a thermosetting resin such as epoxy series, silicone series, polyurethane series, acrylic series, and polyamide series having insulating properties.

In an example, the filling member B may be evenly filled throughout the edge area PA along the plurality of protrusions 140 provided on the circuit board 110.

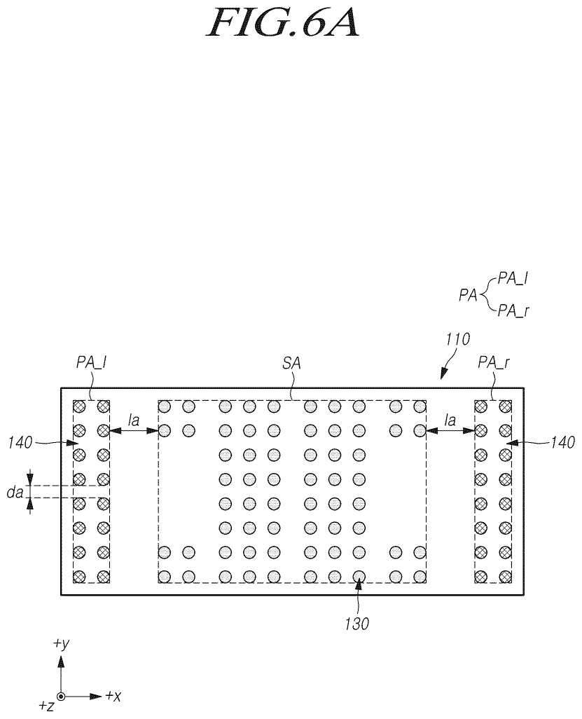

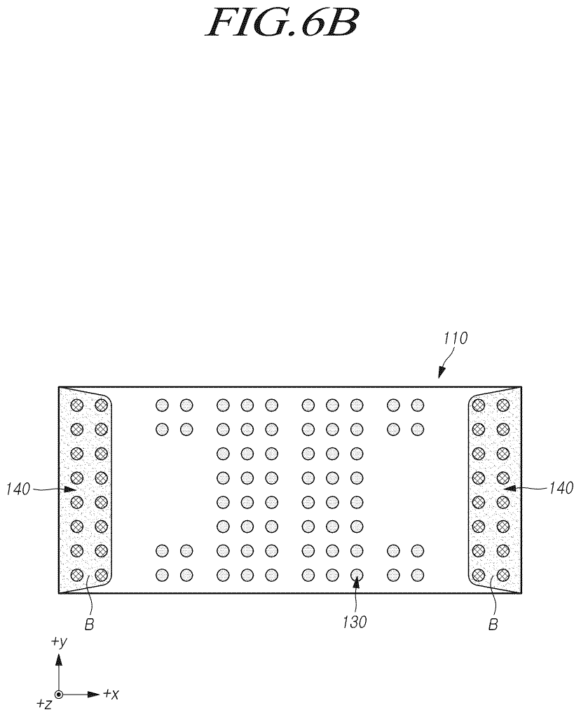

According to an example, the plurality of protrusions 140 may be disposed on the circuit board 110 in at least one or more rows. Hereinafter, various arrangement structures of the plurality of protrusions 140 is described with reference to FIGS. 6 to 16.

FIGS. 6A to 16B are views illustrating arrangements of a plurality of protrusions according to various embodiments of the disclosure.

FIGS. 6A to 16B are views illustrating the plurality of protrusions 140 disposed in at least one or more rows, e.g., two or more rows in a horizontal direction (e.g., ±x direction) on the circuit board 110.

FIG. 6A is a view illustrating the plurality of protrusions 140 disposed in a grid pattern shape in the edge area PA on the circuit board 110 in case of viewing the circuit board 110 from above (e.g., +z-axis direction). FIG. 6B is a view illustrating a filling state of the filling member B in case that the plurality of protrusions 140 are disposed as illustrated in FIG. 6B.

Referring to FIG. 6A, the plurality of protrusions 140 according to an example may be disposed to have at least two or more rows. In an example, each row of the plurality of protrusions 140 may be spaced apart at a predetermined interval along the horizontal direction (e.g., ±x-axis direction) of the circuit board 110.

In an example, the plurality of protrusions 140 may be disposed on each of left and right sides of the soldering area SA, spaced apart from the soldering area SA where the plurality of solder members 130 or connection pads 113a are disposed. The edge area PA may also be formed on each of the left and right sides of the soldering area SA corresponding to the arrangement structure of the plurality of protrusions 140.

According to an example, the plurality of protrusions 140 may be disposed to have an overall grid pattern in the edge area PA in case of viewing the circuit board 110 from above (e.g., +z-axis direction). For example, the plurality of protrusions 140 included in each row may be disposed to face the plurality of protrusions 140 included in other adjacent rows. The plurality of protrusions 140 in each row may be spaced apart from each other by a predetermined spacing da. The spacing da of the plurality of protrusions 140 may be designed to be, e.g., about 0.4 mm, but the disclosure is not limited thereto.

In the grid pattern arrangement structure of the plurality of protrusions 140, a distance 1a between the soldering area SA and the edge area PA may be designed within a range of 0.9 mm to 2.0 mm, e.g., but the disclosure is not limited thereto.

Referring to FIG. 6B, in case that the filling member B fills the edge area PA corresponding to the arrangement structure illustrated in FIG. 6A, the filling member B may flow inward (e.g., in a direction toward the soldering area SA) along gaps formed between the plurality of protrusions 140 in a space between the second electronic component (e.g., the second electronic component 122 of FIG. 2A) and the circuit board 110 by capillary action and then be cured. In this case, the filling member B does not contact the plurality of solder members 130 due to the arrangement structure of the plurality of protrusions 140 and may be evenly filled within the periphery of the edge area PA.

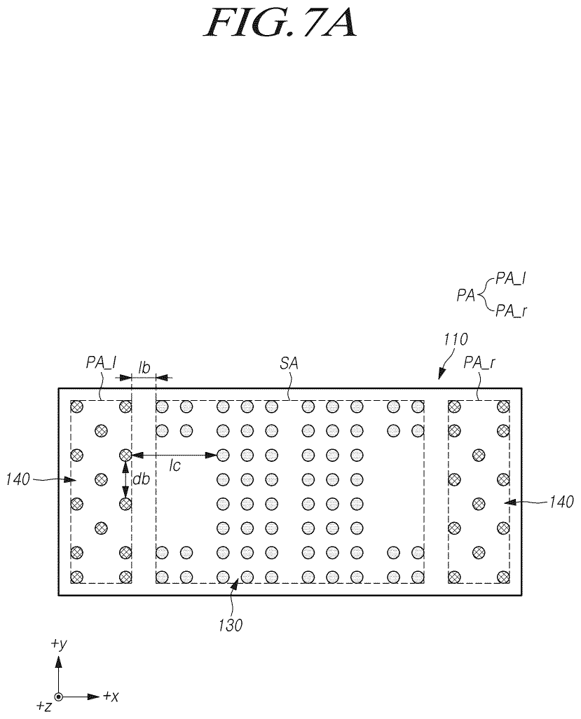

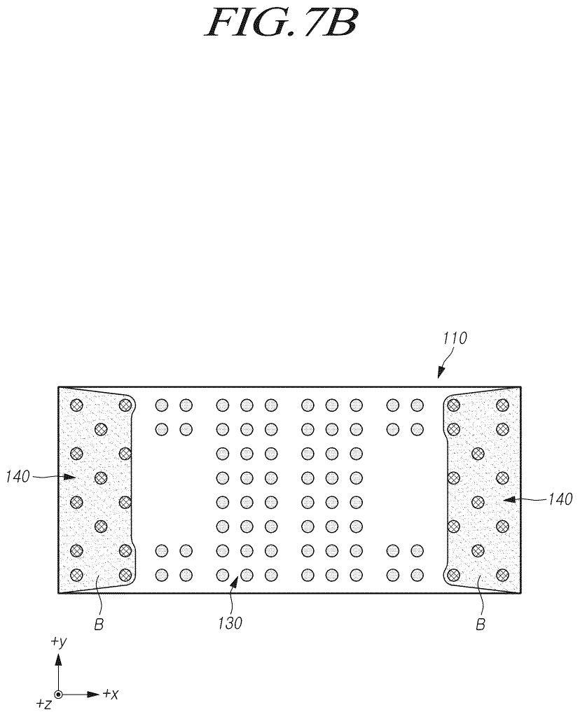

FIG. 7A is a view illustrating at least some of the plurality of protrusions 140 disposed in a cross pattern shape in the edge area PA on the circuit board 110 in case of viewing the circuit board 110 from above (e.g., +z-axis direction). FIG. 7B is a view illustrating a filling state of the filling member B in case that the plurality of protrusions 140 are disposed as illustrated in FIG. 7A.

Referring to FIG. 7A, the plurality of protrusions 140 according to an example may be disposed to have at least two or more, e.g., three rows. In an example, each row of the plurality of protrusions 140 may be spaced apart at a predetermined interval along the horizontal direction (e.g., ±x-axis direction) of the circuit board 110.

In an example, the plurality of protrusions 140 may be disposed on each of left and right sides of the soldering area SA, spaced apart from the soldering area SA where the plurality of solder members 130 are disposed. In this case, the edge area PA may also be formed on each of the left and right sides of the soldering area SA corresponding to the arrangement structure of the plurality of protrusions 140.

According to an example, at least some of the plurality of protrusions 140 may be disposed to have a repeating cross pattern (e.g., X-shaped pattern) along a vertical direction (e.g., ±y-axis direction) in case of viewing the circuit board 110 from above (e.g., +z-axis direction). For example, at least some of the plurality of protrusions 140 included in each row may be disposed not to face the plurality of protrusions 140 included in other adjacent rows. For example, the plurality of protrusions 140 included in each row may be alternately disposed with the plurality of protrusions 140 included in other adjacent rows.

In the cross pattern arrangement structure of the plurality of protrusions 140, each of the plurality of protrusions 140 included in each row may be spaced apart from each other by a predetermined spacing db. The spacing db of the plurality of protrusions 140 may be designed to be, e.g., about 1.0 mm, but the disclosure is not limited thereto.

In the cross pattern arrangement structure, a distance 1b between the soldering area SA and the edge area PA may be designed within a range of 0.1 mm to 0.5 mm, for example. A distance 1c between the solder member 130 disposed at an inner edge of the soldering area SA and the edge area PA may be designed within a range of 1.0 mm to 2.0 mm, for example. However, the disclosure is not limited thereto.

Comparing the arrangement structures of the plurality of protrusions 140 illustrated in each drawing with reference to FIG. 7B and FIG. 6B, as the number of rows in the arrangement structure of the plurality of protrusions 140 illustrated in FIG. 7B increases compared to the arrangement structure of the plurality of protrusions 140 illustrated in FIG. 6B, a filling amount of the filling member B filled between the second electronic component 122 and the circuit board 110 may increase. Accordingly, the second electronic component 122 may be firmly mounted on the circuit board 110.

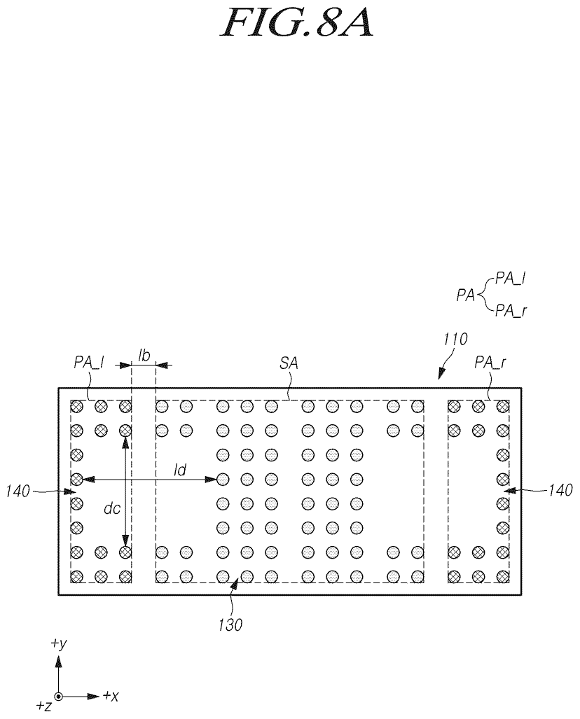

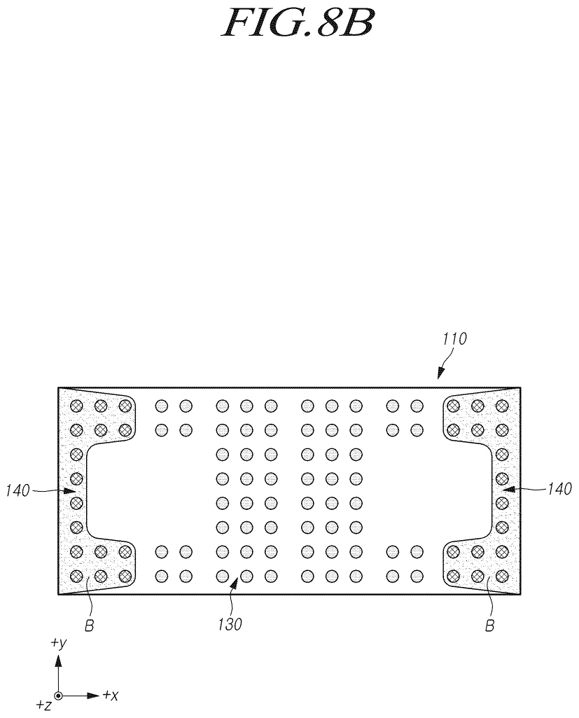

FIG. 8A is a view illustrating the plurality of protrusions 140 disposed in an overall “ [symbol] ” shape or horizontally flipped “ [symbol] ” shape on each of left and right sides of the soldering area SA in case of viewing the circuit board 110 from above (e.g., +z-axis direction). FIG. 8B is a view illustrating a filling state of the filling member B in case that the plurality of protrusions 140 are disposed as illustrated in FIG. 8A.

Referring to FIG. 8A, the plurality of protrusions 140 according to an example may be disposed to have at least two or more, e.g., three rows. In an example, each row of the plurality of protrusions 140 may be spaced apart at a predetermined interval along the horizontal direction (e.g., ±x-axis direction) of the circuit board 110.

In an example, the plurality of protrusions 140 may be disposed on each of left and right sides of the soldering area SA, spaced apart from the soldering area SA where the plurality of solder members 130 are disposed. In this case, the edge area PA may also be formed on each of the left and right sides of the soldering area SA corresponding to the arrangement structure of the plurality of protrusions 140.

According to an example, the plurality of protrusions 140 may be disposed to have an overall “ [symbol] ” shape or horizontally flipped “ [symbol] ” shape on each of left and right sides of the soldering area SA in case of viewing the circuit board 110 from above (e.g., +z-axis direction). For example, the protrusions 140 may not be disposed in a central right area or central left area of the edge area PA. The plurality of protrusions 140 may be disposed to have a shape with a central portion concave toward the soldering area SA in case of viewing the circuit board 110 from above.

In the arrangement structure of the plurality of protrusions 140 illustrated in FIGS. 8A and 8B, a distance 1d between the solder member 130 disposed at an inner edge of the soldering area SA and the protrusion 140 disposed at an outermost side of the edge area PA may be designed within a range of 1.5 mm to 3.0 mm, e.g., but the disclosure is not limited thereto.

A distance de between an upper area (e.g., +y-axis area) and a lower area (e.g., −y-axis area) of the edge area PA may be designed to be about 10 mm, but the disclosure is not limited thereto.

Referring to FIG. 8B, by designing the arrangement structure of the plurality of protrusions 140 corresponding to various arrangement structures of the plurality of solder members 130 in the soldering area SA, a filling direction (or flow direction) of the filling member B filled between the second electronic component 122 and the circuit board 110 may be controlled.

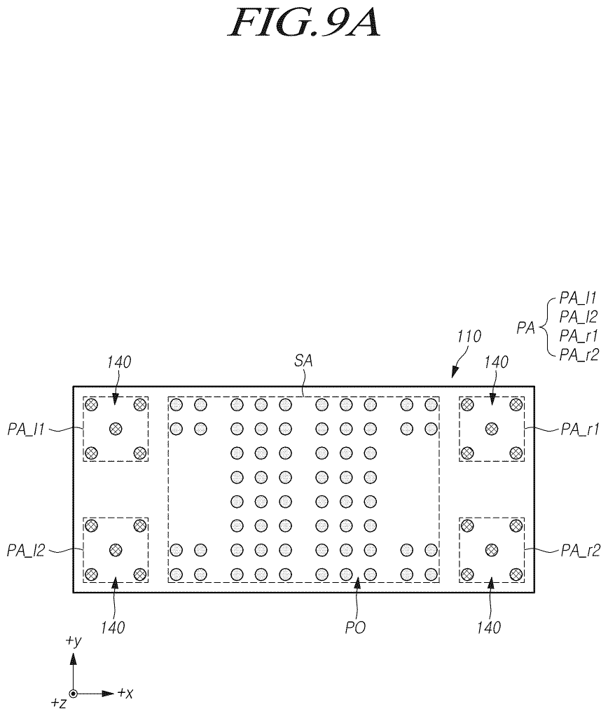

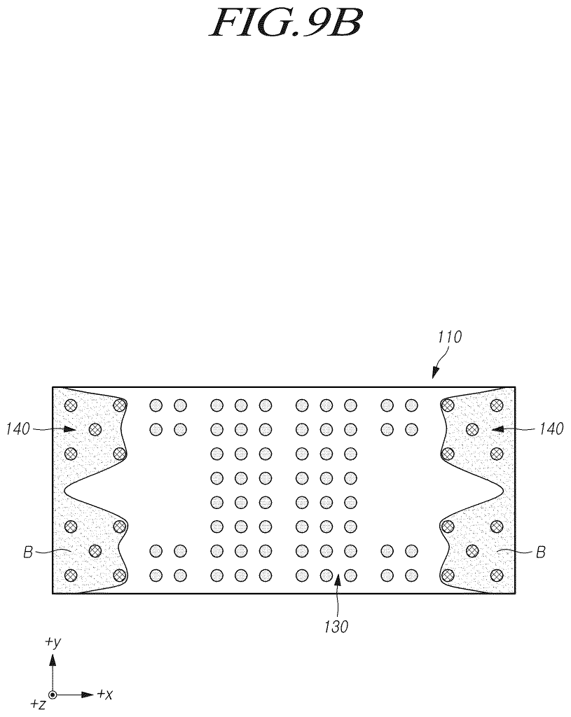

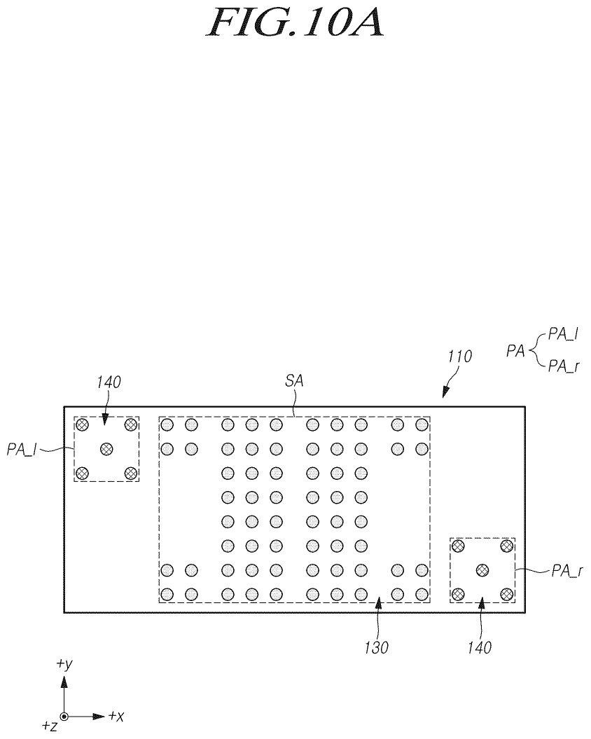

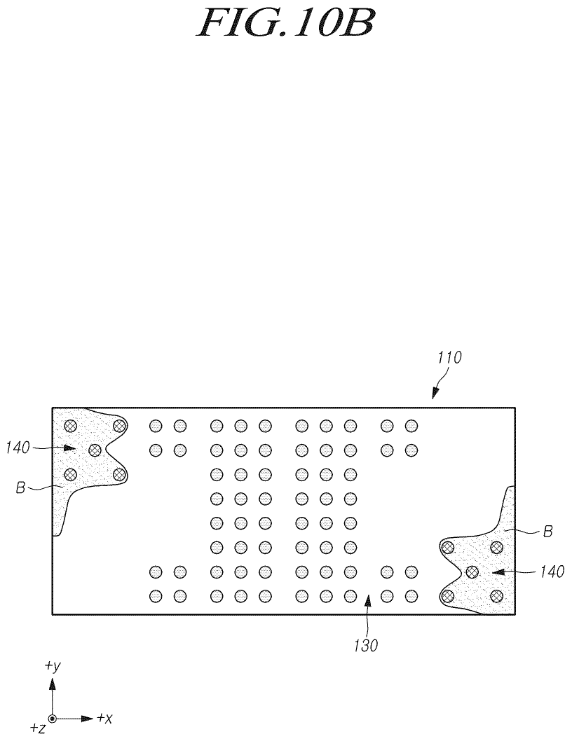

Referring to FIGS. 9A to 10B, the plurality of protrusions 140 according to an example may be disposed in at least one group in an area of the circuit board 110 facing corner portions of an edge of the second electronic component 122. The plurality of protrusions 140 may be disposed to have an overall X shape within the group.

Referring to FIG. 9A, the plurality of protrusions 140 may be disposed in groups at each of upper left, lower left, upper right, and lower right with respect to the soldering area SA in case of viewing the circuit board 110 from above (e.g., +z-axis direction). In this case, the edge area PA may also be divided into an upper left edge area PA_l1, a lower left edge area PA_l2, an upper right edge area PA_r1, and a lower right edge area PA_r2 corresponding to the arrangement structure of the plurality of protrusions 140. The upper left edge area PA_l1 and the lower left edge area PA_l2 may be disposed to be spaced apart at a predetermined interval in a vertical direction (e.g., ±y-axis direction) on a left side (e.g., −x-axis direction) of the soldering area SA. The upper right edge area PA_r1 and the lower right edge area PA_r2 may be disposed to be spaced apart at a predetermined interval in the vertical direction (e.g., ±y-axis direction) on a right side (e.g., +x-axis direction) of the soldering area SA.

Referring to FIG. 9B, in case that the filling member B fills the edge area PA corresponding to the arrangement structure illustrated in FIG. 9A, it may be identified that the filling member B is not filled in empty areas formed between the edge areas PA_l1, PA_l2, PA_r1, PA_r2 as they are spaced apart from each other. In this case, the filling member B may be filled between the second electronic component 122 and the circuit board 110 near four vertices of the second electronic component 122.

Referring to FIG. 10A, unlike illustrated in FIG. 9A, the plurality of protrusions 140 may be disposed in groups in diagonal directions with respect to the soldering area SA in case of viewing the circuit board 110 from above (e.g., +z-axis direction). For example, the plurality of protrusions 140 may be disposed in the upper left edge area PA_l1 and the lower right edge area PA_r2.

Referring to FIG. 10B, in case that the filling member B fills the edge area PA corresponding to the arrangement structure illustrated in FIG. 10A, it may be identified that the filling member B is filled centered on the upper left edge area PA_l1 and the lower right edge area PA_r2. In this case, the filling member B may be filled between the second electronic component 122 and the circuit board 110 near diagonal vertices of the second electronic component 122.

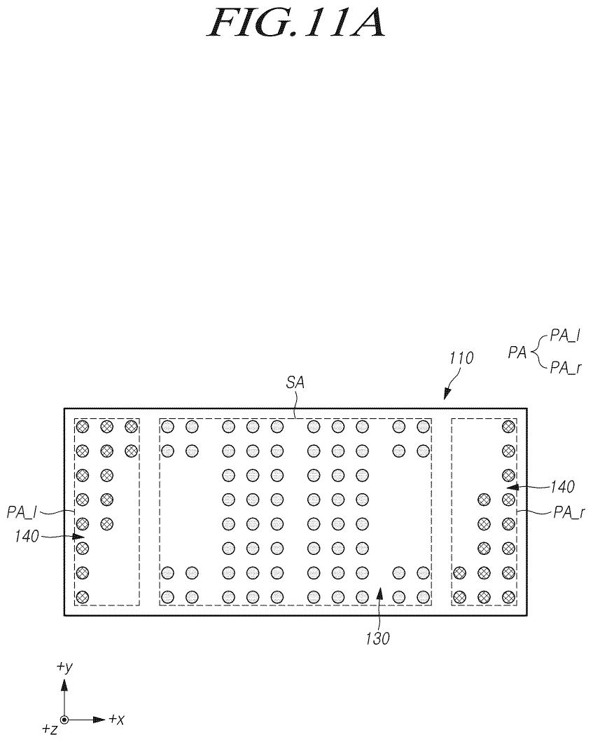

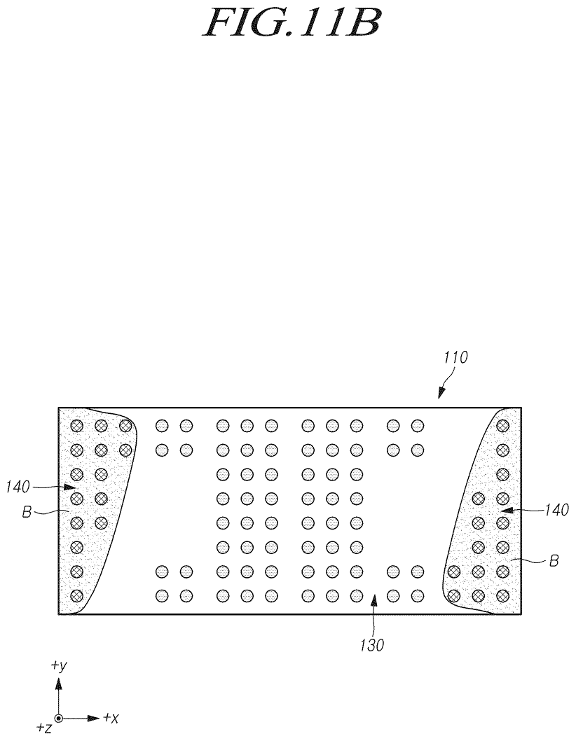

Referring to FIGS. 11A and 11B, the plurality of protrusions 140 may have an arrangement structure in which the number of the plurality of protrusions 140 gradually decreases in a predetermined direction (e.g., −y-axis direction or +y-axis direction).

Referring to FIG. 11A, the plurality of protrusions 140 according to an example may have an arrangement structure in which the number of protrusions decreases in a first direction (e.g., −y-axis direction) in the first edge area PA_l in case of viewing the circuit board 110 from above (e.g., +z-axis direction). In an example, the plurality of protrusions 140 may have an arrangement structure in which the number of protrusions decreases in a second direction (e.g., +y-axis direction) opposite to the first direction in the second edge area PA_r in case of viewing the circuit board 110 from above (e.g., +z-axis direction). For example, the plurality of protrusions 140 may have an inclined arrangement structure or a right triangular arrangement structure in which the number of protrusions decreases or increases in each edge area PA in case of viewing the circuit board 110 from above.

Referring to FIG. 11B, in case that the filling member B fills the edge area PA corresponding to the arrangement structure illustrated in FIG. 11A, the filling member B is filled centered on the plurality of protrusions 140 and may be distributed in an oblique direction on the X-Y plane in case of viewing the circuit board 110 from above.

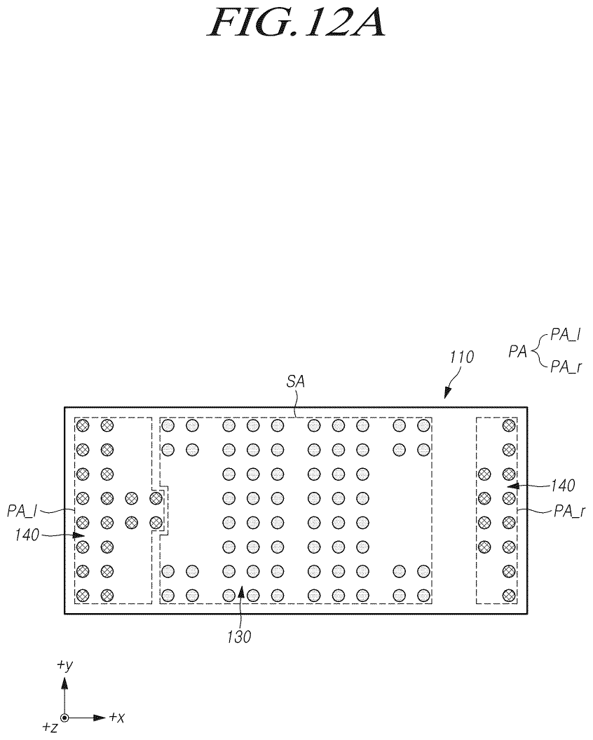

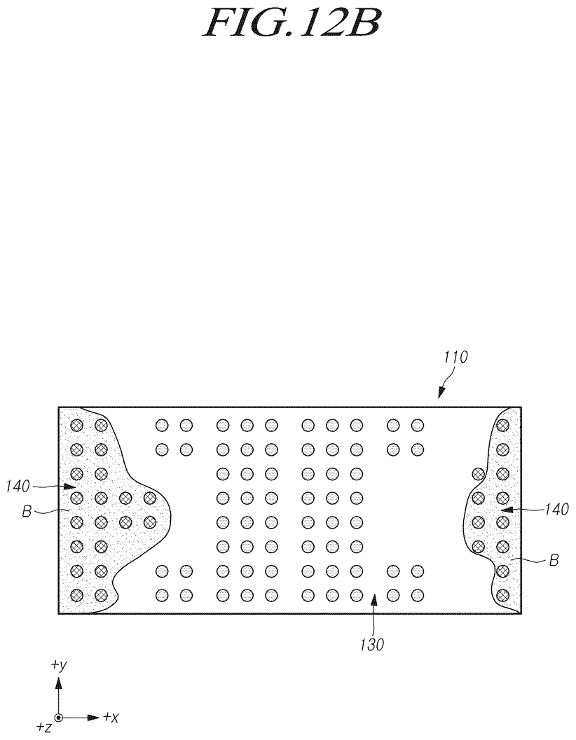

Referring to FIGS. 12A and 12B, the plurality of protrusions 140 according to an example may be disposed to have a left-right asymmetric structure with respect to the soldering area SA. In this case, areas of the first edge area PA_l and the second edge area PA_r formed on each of left and right sides of the soldering area SA may differ from each other.

Referring to FIG. 12A, the plurality of protrusions 140 according to an example may be disposed in four rows in the first edge area PA_l. In an example, the plurality of protrusions 140 may be disposed to have an overall “ [symbol] ” shape in the first edge area PA_l in case of viewing the circuit board 110 from above (e.g., +z-axis direction). For example, the plurality of protrusions 140 may be disposed in four rows with a central portion of the first edge area PA_r convex toward the soldering area SA. In an example, the plurality of protrusions 140 may be disposed to have an overall “ [symbol] ” shape in the second edge area PA_r in case of viewing the circuit board 110 from above (e.g., +z-axis direction). For example, the plurality of protrusions 140 may be disposed in two rows with a central portion of the second edge area PA_r convex toward the soldering area SA. In this case, an area of the first edge area PA_l may be larger than the second edge area PA_r.

Referring to FIG. 12B, in case that the filling member B fills the edge area PA corresponding to the arrangement structure illustrated in FIG. 12A, the filling member B is distributed toward a central portion side of each edge area PA_l, PA_r, and it may be identified that a distribution range of the filling member B is wider in the first edge area PA_l where more protrusions are formed than in the second edge area PA_r.

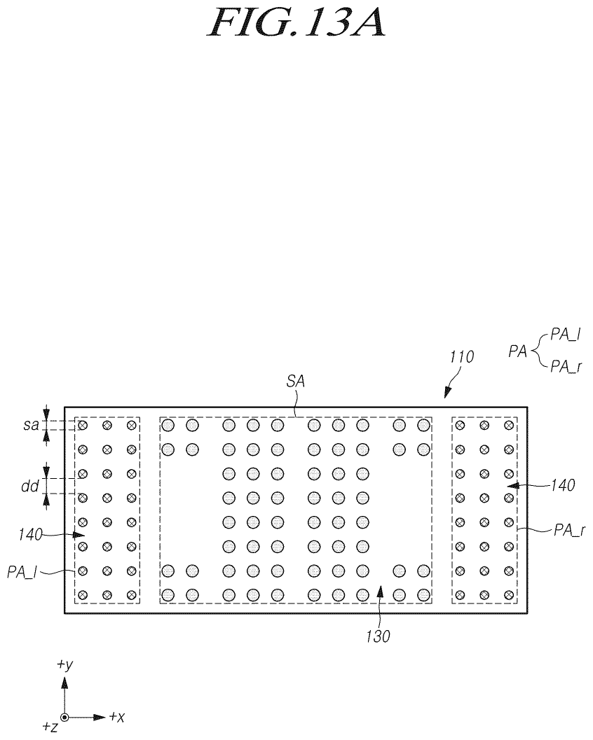

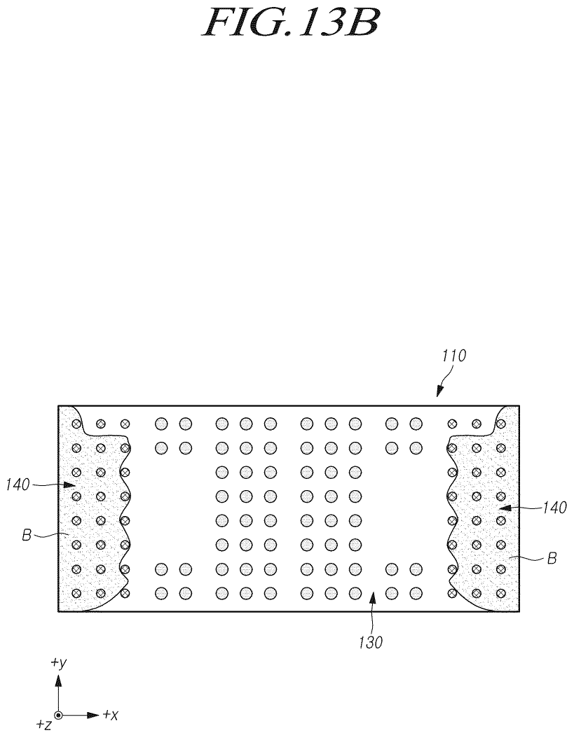

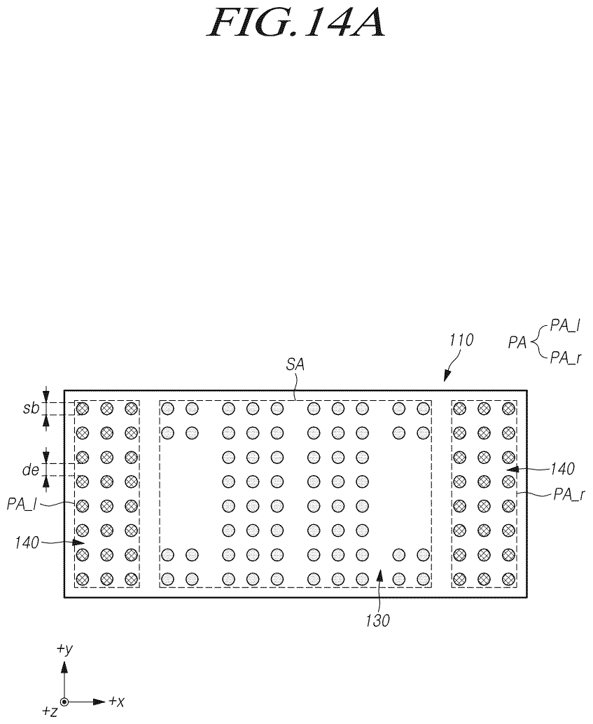

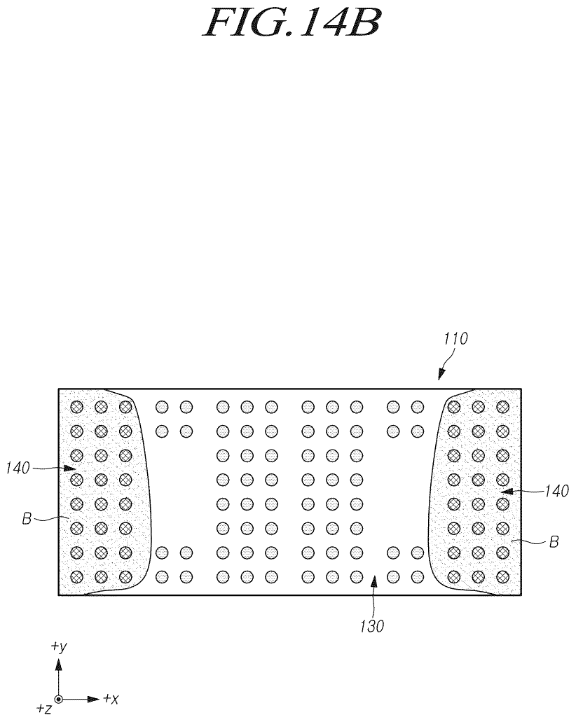

Referring to FIGS. 13A to 14B, the plurality of protrusions 140 according to an example may adjust a distribution range of the filled filling member B by adjusting a size of the protrusions and/or spacing between the protrusions.

Referring to FIGS. 13A and 14A, a diameter (or size) sa of the plurality of protrusions 140 illustrated in FIG. 13A may be designed to be smaller than a diameter (or size) sb of the plurality of protrusions 140 illustrated in FIG. 14A. On the other hand, a spacing dd between the plurality of protrusions 140 illustrated in FIG. 13A may be designed to be wider than a spacing de between the plurality of protrusions 140 illustrated in FIG. 14A.

In this case, a capillary effect by the plurality of protrusions 140 having the arrangement structure of FIG. 14B may be smoother than the arrangement structure of FIG. 13A. Accordingly, it may be identified that the distribution range of the filling member B filled into the edge area PA is distributed wider in FIG. 14B than in FIG. 13A.

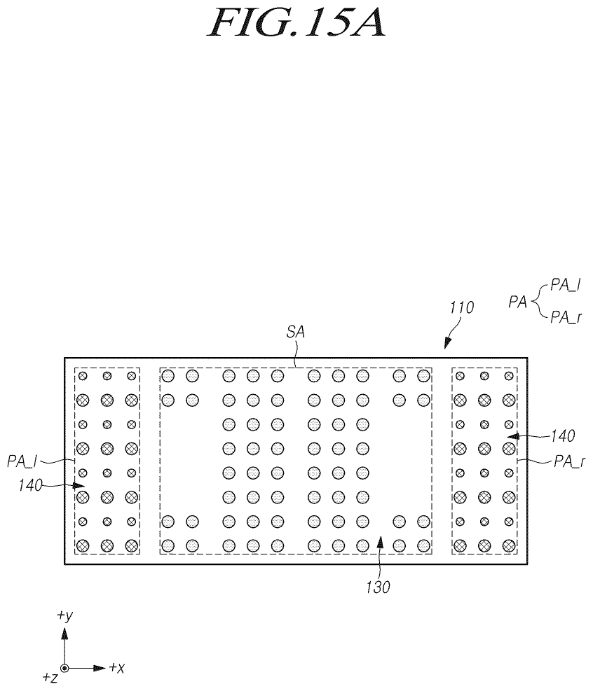

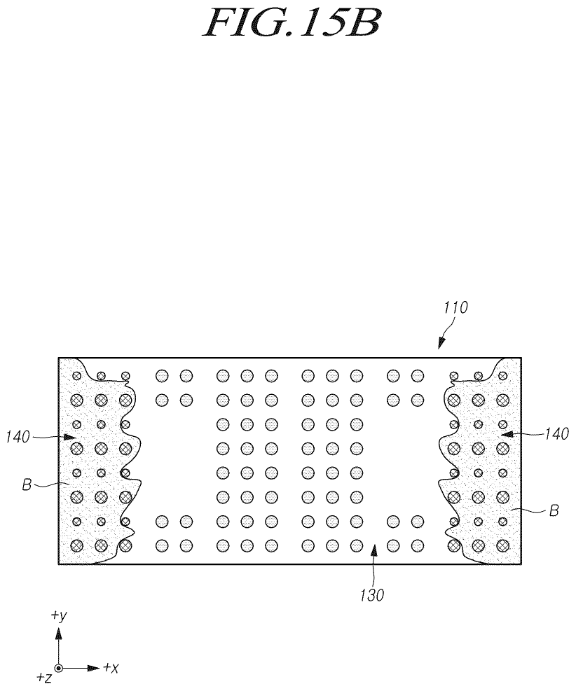

Referring to FIGS. 15A and 15B, in the plurality of protrusions 140 according to an example, protrusions of different sizes may be alternately disposed in each row disposed in the edge area PA. In an example, the size of protrusions included in each row in each edge area PA_l, PA_r may vary in a vertical direction (e.g., ±y-axis direction). For example, in the plurality of protrusions 140 included in each row, small-sized protrusions and large-sized protrusions may be alternately disposed in the vertical direction. In case that the filling member B fills the edge area PA corresponding to the arrangement structure illustrated in FIG. 15A, as illustrated in FIG. 15B, it may be identified that the filling member B is distributed centered on relatively larger protrusions. Such distribution pattern of the filling member B may be caused by a difference in adhesion area between the filling member B and the protrusions.

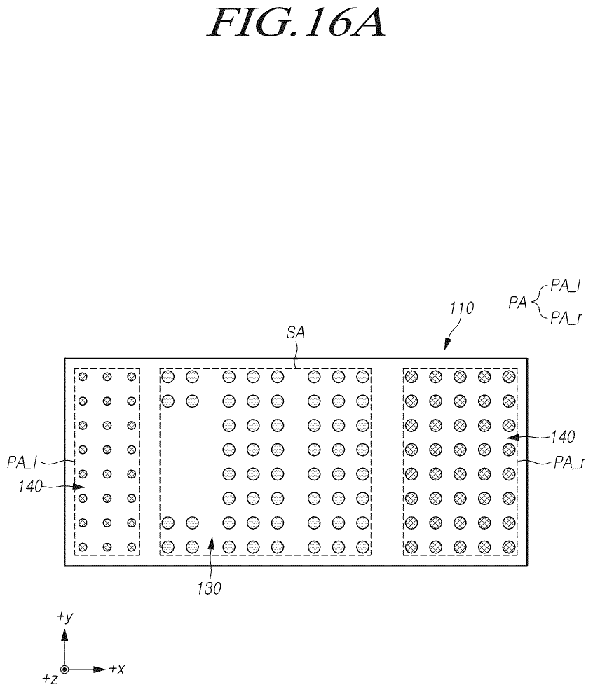

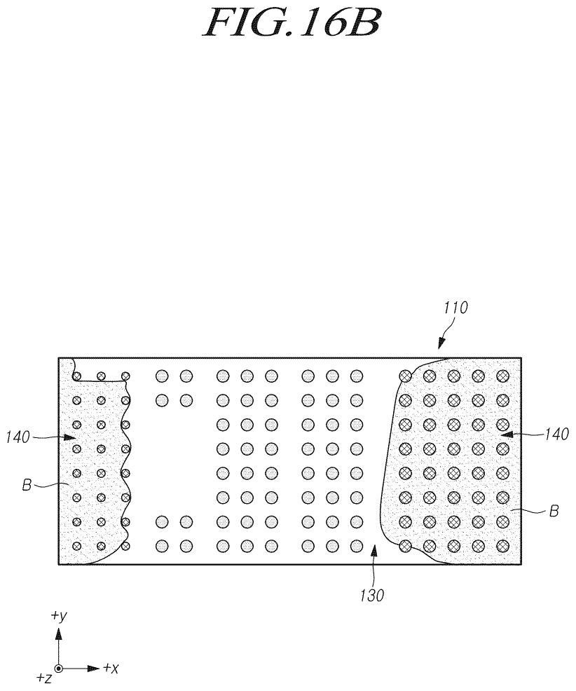

Referring to FIGS. 16A and 16B, in a soldering area SA′ according to an example, in case of viewing the circuit board 110 from above (e.g., +z-axis direction), an overall left-right shape may be formed asymmetrically as an arrangement structure of the plurality of connection pads 113a changes. In this case, the plurality of protrusions 140 according to an example may be disposed to have a left-right asymmetric structure with respect to the soldering area SA′. Further, areas of the first edge area PA_l and the second edge area PA_r formed on each of left and right sides of the soldering area SA′ may differ from each other.

Referring to FIG. 16A, the plurality of protrusions 140 according to an example may be disposed in three rows in the first edge area PA_l, but the disclosure is not limited thereto. In an example, the plurality of protrusions 140 may be disposed to have a grid pattern in the first edge area PA_l. According to an example, the plurality of protrusions 140 may be disposed in five rows in the second edge area PA_r, but the disclosure is not limited thereto. In an example, the plurality of protrusions 140 may be disposed to have a grid pattern in the second edge area PA_r. Further, the plurality of protrusions 140 disposed in the first edge area PA_l may be designed to have a smaller size than the plurality of protrusions 140 disposed in the second edge area PA_r.

In this case, as illustrated in FIG. 16B, in case that the filling member B fills the edge area PA, it may be identified that the distribution range of the filling member B is wider in the second edge area PA_r than in the first edge area PA_l.

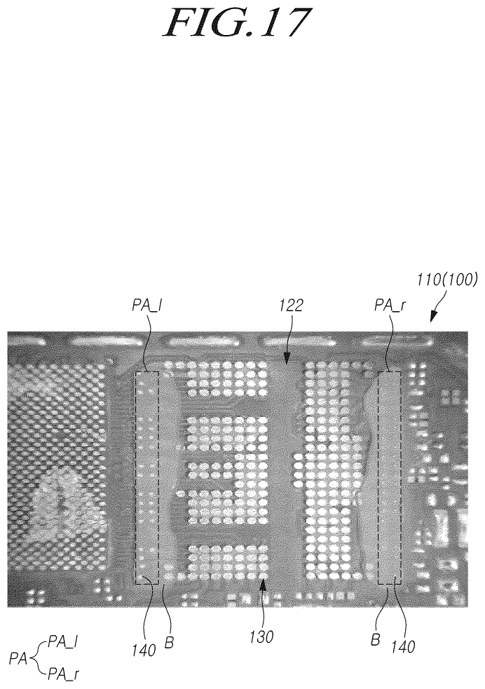

FIG. 17 is a view illustrating a filling range of a filling member on a circuit board according to an embodiment of the disclosure.

Referring to FIG. 17, as described above, by disposing the plurality of protrusions 140 in the edge area PA of the circuit board 110, the filling member B may be evenly filled throughout the edge area PA by capillary action in case of filling the filling member B. Further, contact between the filled filling member B and the plurality of solder members 130 disposed in the soldering area SA may be prevented as much as possible. In this case, electrical performance of the solder member 130 may be ensured, and at the same time, reliability in circumstances such as thermal shock or drop of the second electronic component 122 and the circuit board 110 may be enhanced.

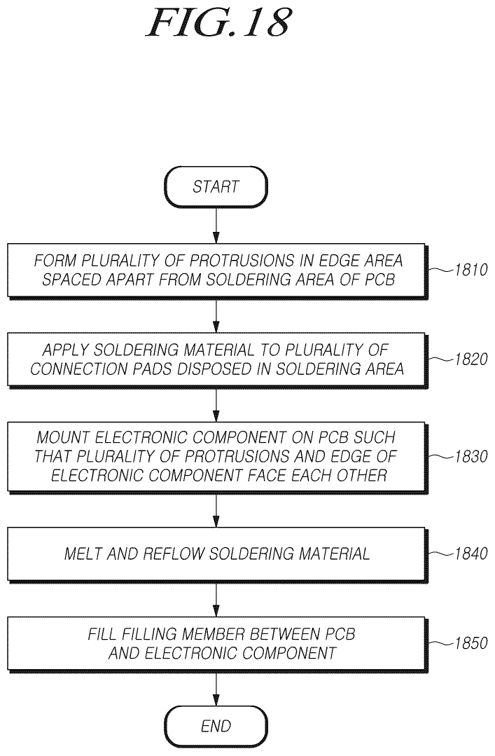

FIG. 18 is a manufacturing process diagram illustrating a printed circuit board assembly according to an embodiment of the disclosure.

FIGS. 19A and 19B are process diagrams illustrating a forming process of a plurality of protrusions according to an embodiment of the disclosure.

FIGS. 20A and 20B are process diagrams illustrating a forming process of a plurality of protrusions according to an embodiment of the disclosure.

Referring to FIG. 18, a method for manufacturing the printed circuit board assembly 100 according to an example may include forming a plurality of protrusions 140 in the edge area PA spaced apart from the soldering area SA of the circuit board 110 at operation 1810. For example, as described above, the plurality of protrusions 140 may be formed by a soldering process of applying and/or curing a soldering material on the plurality of dummy pads 113b provided on the circuit board 110.

According to an example, the plurality of protrusions 140 may not only be formed by the soldering process but also may be formed by a bonding member P composed of a material different from the soldering material. Hereinafter, a forming process of the protrusions 140 using the bonding member (or bonding solution) P is described with reference to FIGS. 19A to 20B.

FIG. 19A is a view illustrating the bonding member P being dispensed on the circuit board 110 by the dispensing device 200. FIG. 19B is a view illustrating the second electronic component 122 being mounted (or disposed) on the circuit board 110 after the bonding member P dispensed on the circuit board 110 of FIG. 19A is cured to form the plurality of protrusions 140.

Referring to FIG. 19A, an operator may apply the bonding member P to an area of the circuit board 110 where the plurality of solder members 130 are not disposed before mounting the second electronic component 122 using the dispensing device (or dispenser) 200.

Referring to FIG. 19B, the operator may apply the bonding member P to the circuit board 110 and then cure it to form the plurality of protrusions 140, and then mount (or dispose) the second electronic component 122 on the circuit board 110 such that the plurality of protrusions 140 and an edge portion of the second electronic component 122 face each other while the plurality of solder members 130 are seated on the connection pads 113a of the circuit board 110.

Thereafter, although not specifically illustrated in this drawing, the operator may fill the filling member B to an edge of the second electronic component 122 and the circuit board 110. In this case, the filled filling member B may flow into an inner space between the second electronic component 122 and the circuit board 110 through the plurality of protrusions 140 and then be cured.

FIG. 20A is a view illustrating the bonding member P being dipped from an external storage container by the stamping device 300 and stamped on the circuit board 110. FIG. 20B is a view illustrating the second electronic component 122 being mounted (or disposed) on the circuit board 110 after the bonding member P stamped on the circuit board 110 of FIG. 20A is cured to form the plurality of protrusions 140.

Referring to FIG. 20A, the operator may dip the bonding member P from an external container storing the bonding member P using the stamping device 300, and then apply the bonding member P to an area of the circuit board 110 where the plurality of solder members 130 are not disposed before mounting the second electronic component 122.

Referring to FIG. 20B, the operator may apply the bonding member P to the circuit board 110 and then cure it to form the plurality of protrusions 140, and then mount (or dispose) the second electronic component 122 on the circuit board 110 such that the plurality of protrusions 140 and an edge portion of the second electronic component 122 face each other while the plurality of solder members 130 are seated on the connection pads 113a of the circuit board 110.

Thereafter, although not specifically illustrated in the drawings, the operator may fill the filling member B to an edge of the second electronic component 122 and the circuit board 110. In this case, the filled filling member B may flow into an inner space between the second electronic component 122 and the circuit board 110 through the plurality of protrusions 140 and then be cured.

As described with reference to FIGS. 19 and 20, in case of forming the plurality of protrusions 140 using the bonding member P, the dummy pads 113b for fixing the soldering material required during the soldering process become unnecessary, so design freedom of the circuit board 110 may be enhanced.

According to an example, the method for manufacturing the printed circuit board assembly 100 may include applying a soldering material to the plurality of connection pads 113a disposed in the soldering area SA at operation 1820.

According to an example, the method for manufacturing the printed circuit board assembly 100 may include mounting (or disposing) the electronic component (e.g., the second electronic component 122) on the circuit board 110 such that the plurality of protrusions 140 and an edge of the electronic component 122 face each other (at operation 1830). In this case, each of the plurality of contact points 125 of the electronic component 122 and the plurality of connection pads 113a of the circuit board 110 may contact upper/lower portions of the plurality of solder members 130.

According to an example, the method for manufacturing the printed circuit board assembly 100 may include melting and reflowing the soldering material by applying heat to the plurality of solder members 130 in a state in which the electronic component 122 is mounted (or disposed) on the circuit board 110 at operation 1840. In this case, the electronic component 122 and the circuit board 110 may be physically and/or electrically connected through the plurality of solder members 130 by melting and then curing the soldering material.

According to an example, the method for manufacturing the printed circuit board assembly 100 may include filling the filling member B between the circuit board 110 and the electronic component 122 at operation 1850. For example, the operator may perform an underfill or sidefill process of filling the filling member B into a space between an edge of the electronic component (e.g., the second electronic component 122) where the plurality of protrusions 140 are located and the circuit board 110. In this case, the filling member B may seep along narrow gaps formed between the plurality of protrusions 140 by capillary action and be evenly distributed in the edge area where the plurality of protrusions 140 are formed.

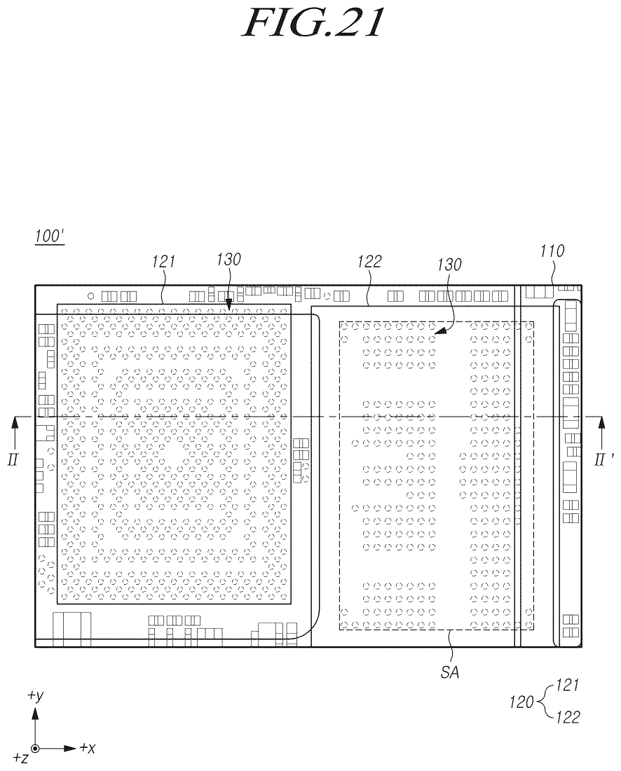

FIG. 21 is a plan view illustrating a printed circuit board assembly according to an embodiment of the disclosure.

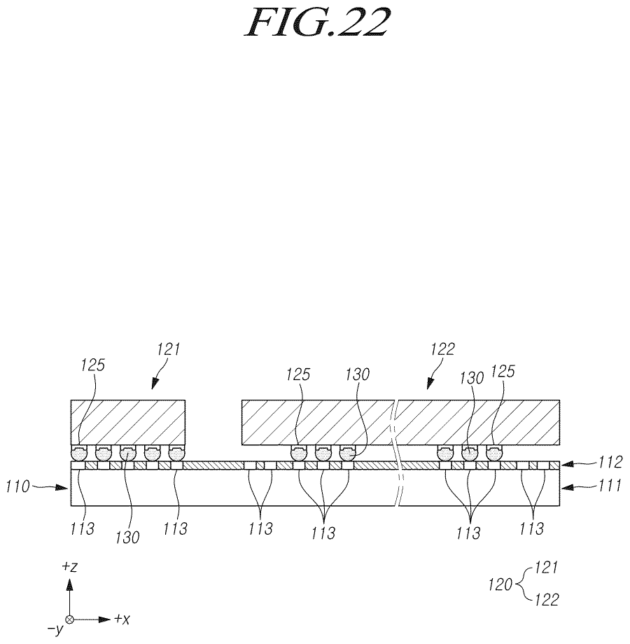

FIG. 22 is a cross-sectional view illustrating the printed circuit board assembly taken along line II-II′ illustrated in FIG. 21 according to an embodiment of the disclosure;

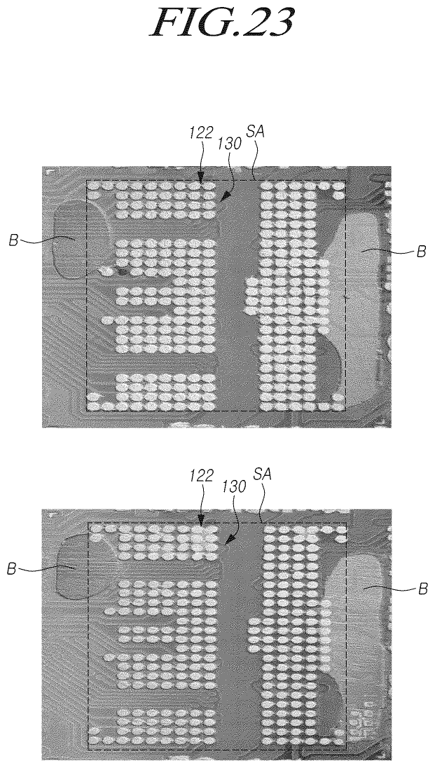

FIG. 23 is a view illustrating a filling range of a filling member in a circuit board according to an embodiment of the disclosure.

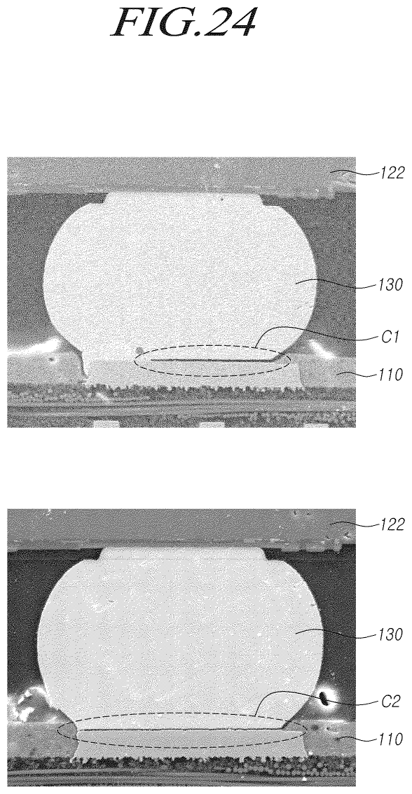

FIG. 24 is a view illustrating a crack state of a solder member occurring in case that a filling member is under-filled according to an embodiment of the disclosure.

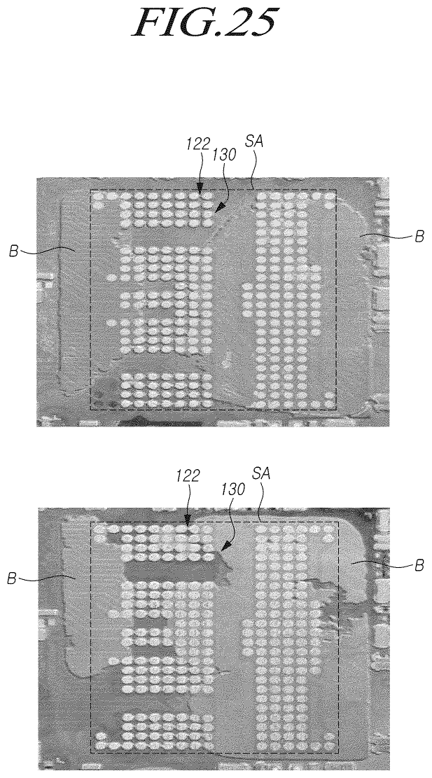

FIG. 25 is a view illustrating a filling range of a filling member on a circuit board according to an embodiment of the disclosure.

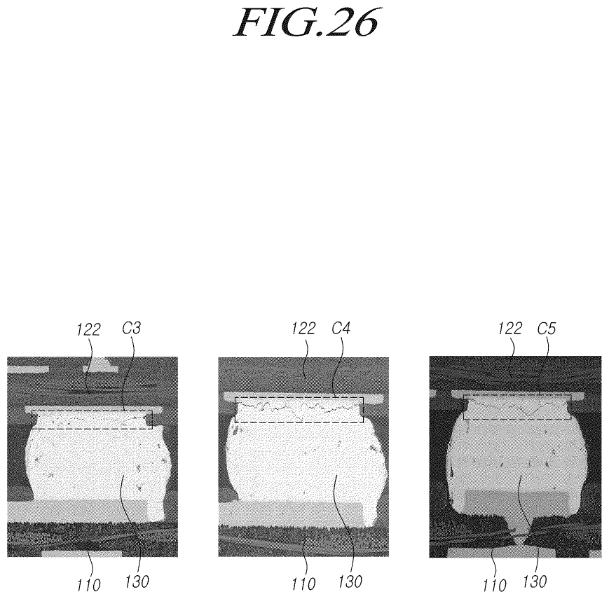

FIG. 26 is a view illustrating a crack state of a solder member occurring in case that a filling member is over-filled according to an embodiment of the disclosure.

Referring to FIGS. 21 and 22, a printed circuit board assembly 100′ according to the comparative example may include the circuit board 110, at least one electronic component 120, and/or the plurality of solder members 130. In describing the printed circuit board assembly 100′ illustrated in FIGS. 21 and 22, the same reference numerals are assigned to components substantially the same as or similar to the printed circuit board assembly 100 illustrated in FIGS. 1, 2A, and 2B, and the description of the components may be replaced with the description of the printed circuit board assembly 100.

In the printed circuit board assembly 100′ according to the comparative example, the soldering area SA where the plurality of solder members 130 connecting the second electronic component 122 and the circuit board 110 are disposed may be smaller than an overall size of the second electronic component 122.

Unlike the printed circuit board assembly 100 according to an example of the disclosure illustrated in FIGS. 1, 2A, and 2B, the printed circuit board assembly 100′ according to the comparative example does not have a plurality of protrusions (e.g., the plurality of protrusions 140 of FIG. 1) provided in a periphery of the soldering area SA on the circuit board 110, specifically in an edge area (e.g., the edge area PA of FIG. 1).

Referring to FIGS. 23 to 26, in the printed circuit board assembly 100′ according to the comparative example, in case of filling the filling member B in a space between the second electronic component 122 and the circuit board 110 after mounting (or disposing) the second electronic component 122 on the circuit board 110, the filling member B frequently fails to be uniformly applied in an overlapping area between the second electronic component 122 and the circuit board 110 including the soldering area SA.

In case that the filling member B is under-filled as illustrated in FIG. 23, the filling member B may not sufficiently protect the plurality of solder members 130, and cracks (e.g., C1, C2 in FIG. 24) occur in the solder member 130 due to repeated external impacts or stress. As a result, the printed circuit board assembly 100′ according to the comparative example has lower reliability in circumstances such as drops compared to the printed circuit board assembly 100 according to the disclosure.

Conversely, in case that the filling member B is over-filled as illustrated in FIG. 25, cracks (e.g., C3, C4, C5 in FIG. 26) occur in the solder member 130 due to thermal expansion/contraction of the filling member B according to heat generation of the solder member 130 during operation of the printed circuit board assembly. As a result, the printed circuit board assembly 100′ according to the comparative example has lower reliability regarding thermal shock compared to the printed circuit board assembly 100 according to the disclosure.

A printed circuit board assembly 100 according to an example of the disclosure may include an electronic component 120. The printed circuit board assembly 100 may include a printed circuit board 110 on which the electronic component 120 is disposed. The printed circuit board assembly 100 may include a plurality of solder members 130 electrically connecting the electronic component 120 and the printed circuit board 110 between the electronic component 120 and the printed circuit board 110. The plurality of protrusions 140 may be disposed on the printed circuit board 110 to be spaced apart from the plurality of solder members 130 and positioned near an edge of the electronic component 120. The printed circuit board assembly 100 may include a filling member B filling the edge of the electronic component 120 between the printed circuit board 110 and the electronic component 120. Distribution of the filling member B may be facilitated by an adhesion force between the filling member B and the plurality of protrusions 140, and a cohesion force of filling the filling member B during the filling of the filling member B in a liquid state between the printed circuit board 110 and the electronic component 120.

According to an example, the distribution of the filling member B may be controlled by at least one of a size of the plurality of protrusions 140, a distance between the plurality of solder members 130 and the plurality of protrusions 140, or a gap between the plurality of protrusions 140 such that the filling member B does not contact the plurality of solder members 130.

According to an example, the filling member B may be formed of at least one of epoxy, silicone, polyurethane, acrylic, or polyamide series which are non-conductive materials.

According to an example, a spacing distance between the plurality of protrusions 140 and the plurality of solder members 130 may be set to 0.1 mm or more such that the filling member B does not contact the plurality of solder members 130 during distribution of the filling member B.

According to an example, the plurality of solder members 130 may be disposed inside the edge of the electronic component 120 on the printed circuit board 110.

According to an example, the plurality of protrusions 140 may have a smaller size than the plurality of solder members 130 such that the filling member B does not contact the plurality of solder members 130 during distribution of the filling member B.

According to an example, each of the plurality of protrusions 140 may have a shape of one of a hemisphere, a cylinder, or a polyhedron.

According to an example, the plurality of protrusions 140 may have a lower height h than the plurality of solder members 130 so as not to contact the electronic component 120.

According to an example, the plurality of protrusions 140 are disposed in two or more rows, and the plurality of protrusions 140 included in each row may be disposed alternately with the plurality of protrusions 140 included in other adjacent rows.

According to an example, the plurality of protrusions 140 are disposed in two or more rows, and the plurality of protrusions 140 included in each row may be disposed to face the plurality of protrusions 140 included in other adjacent rows.

According to an example, the plurality of protrusions 140 are disposed to be spaced apart from each other at an interval, and a spacing d between the plurality of protrusions may be set to 0.4 mm or more such that the filling member B does not contact the plurality of solder members 130 during distribution of the filling member B.

According to an example, the printed circuit board 110 may include a plurality of connection pads 113a on which each of the plurality of solder members 130 is disposed and a plurality of dummy pads 113b on which each of the plurality of protrusions 140 is disposed. Each of the plurality of protrusions 140 may be formed by a soldering process disposing a soldering material on each of the plurality of dummy pads 113b.

According to an example, the plurality of protrusions 140 may be formed by dispensing a bonding member P at intervals along an outer area of the plurality of solder members 130 by a dispensing device 200 on the printed circuit board 110.

According to an example, the plurality of protrusions 140 may be formed by dipping a bonding member P from an external storage container by a stamping device 300, and then the bonding member P is stamped at intervals along an outer area of the plurality of solder members 130 by the stamping device 300.

A method for manufacturing a printed circuit board assembly 100 including a printed circuit board 110 on which an electronic component 120 is disposed according to an example of the disclosure may include forming 1810 a plurality of protrusions 140 in an edge area PA of the printed circuit board 110 spaced apart from a soldering area SA of the printed circuit board 110 where a plurality of solder members 130 are disposed. The method for manufacturing the printed circuit board assembly 100 may include applying 1820 a soldering material to a plurality of connection pads 113a disposed in the soldering area SA. The method for manufacturing the printed circuit board assembly 100 may include disposing 1830 the electronic component 120 on the printed circuit board 110 such that the plurality of protrusions 140 and an edge of the electronic component 120 face each other. The method for manufacturing the printed circuit board assembly 100 may include filling 1850 a filling member B between the plurality of protrusions 140. Distribution of the filling member B may be facilitated by adhesion between the filling member B and the plurality of protrusions 140 and cohesion of the filling member B while the filling member B in a liquid state fills between the printed circuit board 110 and the electronic component 120.

According to an example, the method for manufacturing the printed circuit board assembly 100 may further include melting and reflowing 1840 the soldering material to electrically connect the electronic component 120 mounted on the printed circuit board 110 and the printed circuit board 110.

According to an example, the distribution of the filling member B may be controlled by at least one of a size of the plurality of protrusions 140, a distance between the plurality of solder members 130 and the plurality of protrusions 140, and a gap between the plurality of protrusions 140 such that the filling member B does not contact the plurality of solder members 130.

According to an example, the printed circuit board 110 may include a plurality of connection pads 113a on which each of the plurality of solder members 130 is disposed and a plurality of dummy pads 113b on which each of the plurality of protrusions 140 is disposed. Each of the plurality of protrusions 140 may be formed by a soldering process disposing a soldering material on each of the plurality of dummy pads 113b.

According to an example, the plurality of protrusions 140 may be formed by dispensing a bonding member P at intervals along an outer area of the plurality of solder members 130 by a dispensing device 200 on the printed circuit board 110.

According to an example, the plurality of protrusions 140 may be formed by dipping a bonding member P from an external storage container by a stamping device 300, and then the bonding member P is stamped at intervals along an outer area of the plurality of solder members 130 by the stamping device 300.

While the disclosure has been shown and described with reference to various embodiments thereof, it will be understood by those skilled in the art that various changes in form and details may be made therein without departing from the spirit and scope of the disclosure as defined by the appended claims and their equivalents.

What is claimed is:

1. A printed circuit board assembly (PBA) comprising:
an electronic component;
a printed circuit board (PCB) on which the electronic component is disposed;
a plurality of solder members electrically connecting the electronic component and the PCB between the PCB and the electronic component;
a plurality of protrusions disposed to be spaced apart from the plurality of solder members on the PCB and positioned near an edge of the electronic component; and
a filling member filling the edge of the electronic component between the PCB and the electronic component,
wherein distribution of the filling member is facilitated by:
an adhesive force between the filling member and the plurality of protrusions, and
a cohesive force of the filling member during filling of the filling member in a liquid state between the PCB and the electronic component.

2. The PBA according to claim 1, wherein the distribution of the filling member is controlled by at least one of a size of the plurality of protrusions, a distance between the plurality of solder members and the plurality of protrusions, or a gap between the plurality of protrusions such that the filling member does not contact the plurality of solder members.

3. The PBA according to claim 1, wherein the filling member is formed of at least one of epoxy, silicone, polyurethane, acrylic, or polyamide series, which are non-conductive materials.

4. The PBA according to claim 1, wherein a spacing distance between the plurality of protrusions and the plurality of solder members is set to 0.1 mm or more such that the filling member does not contact the plurality of solder members when the filling member is distributed.

5. The PBA according to claim 1, wherein the plurality of solder members are disposed inside the edge of the electronic component.

6. The PBA according to claim 1, wherein the plurality of protrusions has a smaller size than the plurality of solder members such that the filling member does not contact the plurality of solder members when the filling member is distributed.

7. The PBA according to claim 1, wherein each of the plurality of protrusions has a hemispherical shape, a cylinder shape, or polyhedron shape.

8. The PBA according to claim 1, wherein each of the plurality of protrusions has a height lower than that of the plurality of solder members so as not to contact the electronic component.

9. The PBA according to claim 1,
wherein the plurality of protrusions are arranged in two or more columns, and
wherein a plurality of protrusions included in each column are alternately arranged with a plurality of protrusions included in other adjacent columns.

10. The PBA according to claim 1,
wherein the plurality of protrusions are arranged in two or more columns, and
wherein a plurality of protrusions included in each column are arranged to face a plurality of protrusions included in another adjacent column.

11. The PBA according to claim 1,
wherein the plurality of protrusions are arranged spaced apart from each other by a distance, and
wherein the distance between the plurality of protrusions is set to 0.4 mm or more such that the filling member does not contact the plurality of solder members when the filling member is distributed.

12. The PBA according to claim 1,
wherein the PCB includes a plurality of connection pads on which each of the plurality of solder members is disposed and a plurality of dummy pads on which each of the plurality of protrusions is disposed, and
wherein each of the plurality of protrusions is formed by a soldering process of disposing a soldering material on each of the plurality of dummy pads.

13. The PBA according to claim 1, wherein the plurality of protrusions are formed by dispensing a bonding member at intervals along an outer region of the plurality of solder members by a dispensing device on the PCB.

14. The PBA according to claim 1, wherein the plurality of protrusions are formed by:
dipping a bonding member from an external storage container by a stamping device, and
stamping the bonding member at intervals along an outer region of the plurality of solder members by the stamping device.

15. A method of manufacturing a printed circuit board assembly (PBA) including a printed circuit board (PCB) on which an electronic component is mounted, the method comprising:
forming a plurality of protrusions on an edge area of the PCB spaced apart from a soldering area of the PCB where a plurality of solder members are disposed;
applying a soldering material to a plurality of connection pads disposed in the soldering area;
mounting the electronic component on the PCB such that the plurality of protrusions and an edge of the electronic component face each other; and
filling a filling member with the plurality of protrusions disposed between the mounted electronic component and the PCB,
wherein distribution of the filling member is facilitated by:
an adhesive force between the filling member and the plurality of protrusions; and
a cohesive force of the filling member during filling of the filling member in a liquid state between the PCB and the electronic component.

16. The method according to claim 15, further comprising:
melting and reflowing the soldering material to electrically connect the mounted electronic component mounted and the PCB.

17. The method according to claim 15, wherein the distribution of the filling member is controlled by at least one of a size of the plurality of protrusions, a distance between the plurality of solder members and the plurality of protrusions, or a gap between the plurality of protrusions such that the filling member does not contact the plurality of solder members.

18. The method according to claim 15,
wherein the PCB includes the plurality of connection pads on which each of the plurality of solder members is disposed and a plurality of dummy pads on which each of the plurality of protrusions is disposed, and
wherein each of the plurality of protrusions is formed by a soldering process disposing the soldering material on each of the plurality of dummy pads.

19. The method according to claim 15, wherein the plurality of protrusions are formed by dispensing a bonding member at intervals along an outer area of the plurality of solder members by a dispensing device on the PCB.

20. The method according to claim 15, wherein the plurality of protrusions are formed by dipping a bonding member from an external storage container by a stamping device, and the bonding member is stamped at intervals along an outer area of the plurality of solder members by the stamping device.
